(19) United States
(12) Patent Application Publication
(10) Pub. No.: US 2001/0017155 A1
(43) Pub. Date: Aug. 30, 2001

(54) Hole-transporting polymers

(76) Inventors: Erika Bellmann, Pasadena, CA (US); Sankaran Thayumanavan, Monrovia, CA (US); Stephen Barlow, Dorset (GB); Robert H. Grubbs, So. Pasadena, CA (US); Seth R. Marder, Tucson, AZ (US); Bernard Kippelan, Tucson, AZ (US); Neal R. Armstrong, Tucson, AZ (US)

Correspondence Address: Pillsbury Winthrop LLP, Intellectual Property Group, Fifth Floor, 50 Fremont Street, San Francisco, CA, 94105, US

(21) Appl. No.: 09/780,314

(22) Filed: Feb. 8, 2001

Related U.S. Application Data
(62) Division of application No. 09/289,931, filed on Apr. 9, 1999, now abandoned.
(60) Provisional application No. 60/081,175, filed on Apr. 9, 1998.
(60) Provisional application No. 60/083,260, filed on Apr. 27, 1998.

(51) Int. Cl. H01M 6/30; C08G 69/00; C08G 64/00; H01L 31/00

(52) U.S. Cl. 136/263; 429/111; 528/203; 528/204

(57) ABSTRACT

Polymers comprising triarylamine substituent monomers. The polymers are products of anionic or radical polymerization of monovinylated triarylamine monomers or of ROMP polymerization of monomers comprising a triarylamine component, a linker component, and a cyclic olefin that is capable of undergoing a ring-opening polymerization reaction. The resulting polymers possess hole-transporting properties and are useful as hole transport layers in light-emitting diodes or as components of photorefractive materials.

This application claims the benefit of priority to U.S. provisional applications Serial No. 60/081,175, filed Apr. 9, 1998 and Serial No. 60/083,260, filed Apr. 27, 1998.

Development of the invention was supported in part by Grant No. N00014-95-1-1319 awarded by the United States Navy. The U.S. Government may have certain rights in this invention.

### FIELD OF THE INVENTION

The present invention relates generally to organic materials which exhibit hole transport properties. More particularly, the present invention relates to hole-transporting organic polymers which include triarylamine substituents.

### BACKGROUND OF THE INVENTION

In general, compounds that are amenable to injection mechanisms and are able to reversibly form radical cations (i.e. accept and donate positive charge without decomposition) exhibit hole transport properties. Most typically, hole transport materials are used to improve the device performance of organic light emitting diodes (OLEDs) by being deposited as an additional layer between the anode and the luminescent layer.

Research interest in inorganic light-emitting diodes (OLEDs)(Tang, C. et al., Appl Phys Lett 51:913 (1987); Sheats, J. et al., Science 273:884 (1996)) continues to grow as their performance approaches a commercially viable level for applications such as low-cost, flat panel displays. In order to be useful, these devices must have high brightness and efficiency while requiring a low operating voltage. Multilayer devices consisting of thermally deposited hole transport (HTL) and emission layers have been shown to have high performance and good operational stability (Jabbour, G. et al., Appl Phys Lett 71:1762 (1997); Van Slyke, S. et al., Appl Phys Lett 69:2160 (1996)). The HTL typically consists of a N,N-diphenyl-N,N-(m-tolyl)benzidine (TPD) or similar compound which is known to have high hole mobility. TPD also has a high ionization potential (IP) which is well positioned between the work function of indium-tin-oxide (ITO) (−4.7 eV) and the IP of many emission materials. Initial studies addressing the effects of varying the IP of the HTL on the device performance have led to differing results (Okutsu, S. et al., IEEE Trans Electron Devices 44:1302 (1997); Tamoto, N. et al., Chem Mater 9:1077 (1997)). However, more recent studies have shown that the device quantum efficiency increases as the difference between the ionization potential of the HTL and the emission layer is decreased (Roitman, D. et al., J Sel Topics Quantum Electron 4:58 (1998); Giebeler, C. et al., J Appl Phys 85:608 (1999)). These studies have generally been done using thermally deposited small-molecule hole transport materials. One disadvantage to this approach is that the morphological properties of the HTL film are affected by the particular molecular design. Possible crystallization of the hole transport material and poor interfacial contact with the ITO anode result in decreased device performance. The stability of the hole transport material is important to device performance while maintaining a consistent film morphology.

As OLEDs have become more viable for commercial and industrial applications, the use of polymers as the hole transport layer (“HTL”) has been widely explored. The general interest in polymeric hole-transporting materials is due to their potential diversity and improved processability characteristics. In contrast to small organic molecules, polymeric hole transport materials do not undergo crystallization and exhibit an improved interfacial contact with ITO (indium-tin-oxide), the most commonly used anode for OLEDs (Tsutsui, T. MRS Bulletin, June, 1997 p.39; Yang, Y. MRS Bulletin, June, 1997, p.39 and references therein). Good processability, for example, by spin-casting or spray-coating, allows the fabrication of large-area and flexible devices from soluble polymers that may not otherwise be possible with inorganic or low molecular weight organic materials. Moreover, modification of the organic polymers by substituents on the polymeric backbone can improve characteristics such as electronic properties, solubility and crosslinkability.

Photorefractive materials are blends of a molecular hole transport material and a non-linear optical chromophore within a neutral polymeric host. In addition to their use in OLEDs, hole-transporting polymers may also be used to make improved photorefractive materials (Nalwa, H. et al., Non-Linear Optics of Organic Molecules and Polymers, CRC Press, New York, 1997).

### SUMMARY OF THE INVENTION

According to the invention there are provided polymers made up of monomeric units comprising a vinyl group and a triarylamine group having the structure of Formula I. A vinylated triarylamine monomer can comprise aryl radicals that are fused or unfused, the same or different, substituted or unsubstituted. In preferred embodiments the aryl radicals are selected from the group consisting of phenyl, biphenyl, anthracenyl, phenanthracenyl, naphthyl, fluorenyl and pyrenyl. Substituents on the aryl rings are preferably selected from the group consisting of hydroxyl, thiol, thioether, halogen, amine, imine, carboxylic acid or carboxylate, carboxylamine, carbamide, nitro, isocyanate, carbodiimide, carboalkoxy and another aryl group. The functional group can be attached to the aryl ring by a C₁ to C₂₀ alkyl or C₂ to C₂₀ alkenyl or alkynyl group. Particularly preferred are polymers wherein the monomeric units comprise triphenylamine or a TPD group. The polymers of the invention may be homopolymers made up of identical monomeric units, or they can be copolymers or block polymers made up of a combination of different monomeric units.

According to another aspect of the invention there is provided a polymerizable monomeric unit comprising a triarylamine group having the structure of Formula I, a linker and a cyclic olefin. The monomeric unit has the structure of Formula II, wherein R¹ is a cyclic olefin, x and y are either zero or 1, and w and z are zero or any positive integer. In preferred embodiments of this aspect of the invention the linker component is selected from the group consisting of C₁ to C₂₀ alkyl, C₂ to C₂₀ alkenyl, C₂ to C₂₀ alkynyl and aryl groups. In preferred embodiments also, the cyclic olefin moiety is selected from the group consisting of norbornene, norboranadiene, cyclopentene, dicyclopentadiene, cyclobutene, cycloheptene, cyclooctene, 7-oxanorbornene, 7-oxanorbornadiene, and cyclododecene. In a particularly preferred embodiment of this aspect of the invention, the aryl rings are each a substituted or unsubstituted phenyl group, R¹ is a substituted or unsubstituted norbornene, w, x, and y are either zero or 1 and Z is an integer from 0 to 18. In yet another preferred embodiment, w, x, and y are either zero or 1, and z is less than 5. The invention also provides a polymer according to this aspect of the invention wherein any of the triarylamine, linker and cyclic olefin components can be further substituted with one or more substituents selected from the group consisting of halides, C₁ to C₂₀ alkyl, C₁ to C₂₀ alkenyl, C₁ to C₂₀ alkynyl, C₁ to C₂₀ alkoxy and aryl, or further include one or more functional groups. These functional groups can be selected from the group consisting of halides, hydroxyl, thiol, thioether, ketone, aldehyde, ester, ether, amine, imine, amide, nitro, carboxylic acid, disulfide, carbonate, isocyanate, carbodiimide, carboalkoxy and carbamate.

### BRIEF DESCRIPTION OF THE DRAWINGS

FIG. 1 is a schematic of the typical structure of a two-layer LED.

FIG. 2 is a plot of the external quantum efficiency versus the bias voltage for different triarylamine substituted poly(norbornene) derivatives as hole transport layer in a two-layer LED (ITO/poly(norbornene)-TPA/Alq₃/Mg).

FIG. 3 is a plot of the light output versus bias voltage for different triarylamine substituted poly(norbornene) derivatives as hole transport layer in a two layer LED (ITO/poly(norbornene)-TPA/Alq₃/Mg).

FIG. 4 is a plot of the external quantum efficiency versus the bias voltage for both a crosslinked and uncrosslinked triarylamine substituted poly(norbornene), poly-26, as the hole transport layer in a two-layer LED (ITO/poly(norbornene)-TPA/Alq_{3/}Mg).

FIG. 5 is a plot of the light output versus the bias voltage for both a crosslinked and uncrosslinked triarylamine substituted poly(norbornene), poly-26, as the hole transport layer in a two-layer LED (ITO/poly(norbornene)-TPA/Alq₃/Mg).

FIG. 6 shows the structure of TPD derivative hole transport polymers used in preparing a hole transport layer in an organic light-emitting diode.

FIG. 7a is a graphical representation of current density (mA/cm²) vs. applied voltage (V) for ITO/polymer 40 nm/Alq₃ 60 nm/Mg 150 nm devices where the polymer is P1, P2 or P3.

FIG. 7a inset: Current density (mA/cm²) vs. applied voltage (V) for ITO/small-molecule TPD 90 nm/Al; 150 nm (open) and ITO/polymer P2 90 nm/Al 150 nm (closed) devices.

FIG. 7b is a graphical representation of luminance (cd/m²)(closed) and exernal quantum efficiency (% photons/electron)(open) vs. applied voltage (V) for devices in FIG. 7a.

FIG. 8 is a graphical representation of luminance (cd/m²) (closed) and external luminous efficiency (1 m/W) (opem) vs. applied voltage (V) for ITO/polymer P3 40nm/Alq₃:quinacridone (0.5% by wt) 60 nm/LiF 0.8 nm/A. 150 nm device.

### DETAILED DESCRIPTION OF THE INVENTION

The present invention relates to polymer products comprising triarylamine substituents that are useful in various applications as hole-transporting materials. In general, the monomers from which the polymers are prepared comprise a triarylamine component that is converted to a suitable polymerizable form by vinylation or alternatively, by attachment to a linker component and a cyclic olefin that is capable of undergoing a ring-opening polymerization reaction. These polymerizable monomers are converted to polymers by processes such as, for example, ring-opening metathesis polymerization (ROMP), anionic polymerization or radical polymerization. The product polymers are from 5,000 to 108 daltons, and preferably from 5,000 to 50,000 daltons in size.

In addition to hole-transporting properties, the polymers generally are soluble in common organic solvents, are crosslinkable and exhibit a high glass transition temperature.

The solubility of the inventive polymers allows the hole-transporting layer (“HTL”) to be fabricated using spin casting methods instead of the more expensive and involved vacuum vapor deposition methods. Once formed, the polymers are preferably crosslinked such that the HTL is no longer soluble so that the next layer may also be fabricated using spin casting. Otherwise, the next layer would have to be formed using vapor deposition since the solvents used during spin casting would also destroy the previously formed hole-transporting layer.

The high glass transition temperature of the polymers improves the overall device stability, especially thermal stability. Finally, crosslinking the hole-transporting polymer improves overall device stability, especially thermal stability. In addition, because the inventive polymers are crosslinkable after polymerization, multiple layers may be fabricated. For example, crosslinking of the hole transport layer after deposition will result in the material becoming insoluble. As a result, a second polymer layer may be subsequently deposited using spin casting on top of the crosslinked, and thus insoluble, hole transport layer.

The polymers of the invention may be used, for example, as the hole transport layer in LED devices. Another use of these polymers is as a component of photorefractive materials. In general, photorefractive materials are blends of a molecular hole transport material and a non-linear optical chromophore within a neutral polymeric host. Because the inventive polymers could function both as the hole transport material and as the polymeric host (resulting in at least one less component), the likelihood of material degradation through phase separation is reduced. By replacing the neutral polymeric host which does not contribute to the photorefractive effect, the device efficiency per unit of mass would also improve.

Another application of these polymers involves a particular kind of solar cell. Wide-bandgap semiconductors, in particular, titanium dioxide, can be sensitized to solar radiation. Titanium dioxide-based solar cells have been widely studied. A potential disadvantage of these devices is the need for a liquid junction. Recently, it has been shown that the liquid can be replaced by a solid organic hole transport material (Bach, U. et al. Nature 395:583 (1998)). This discovery opens up a potential new application for hole-transporting polymers. Triarylamine Monomers: The triarylamine components of the polymers of the invention have the general formula I:

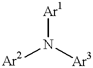

wherein Ar¹, A², and Ar³ are each independently any aryl or fused-ring aromatic compound. The term “aryl,” when used alone, means an aromatic radical, whether fused or not, derived from an aromatic hydrocarbon molecule by removal of one hydrogen atom. Illustrative examples of suitable aryls or fused-ring aromatic compounds incorporated in the triarylamine groups of the invention include, but are not limited to, anthracenyl, biphenyl, fluorenyl, napthyl, phenyl, phenanthracenyl, and pyrenyl. Other aryl groups for these compounds are triphenyl, benzanthracenyl, naphthacenyl, fluoroanthracenyl, acephenanthracenyl, aceanthrycenyl, and chrysenyl.

Three examples of especially preferred triarylamine groups for the polymers of the invention are shown below.

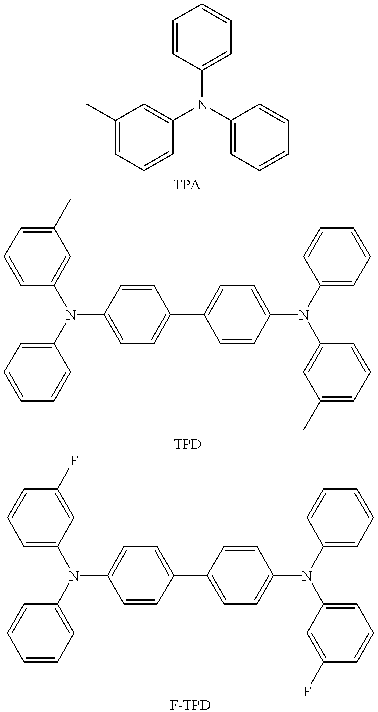

In a first step of synthesizing the polymers of the invention the monomers are converted into polymerizable vinylated triarylamine components. In general, the triarylamine monomers of the present invention are prepared by monobrominating a triarylamine compound of the general formula N(Ar¹) (Ar²) (Ar³) wherein Ar¹, Ar², and Ar³ are each independently any aryl compound, and replacing the bromide in the resulting compound with a vinyl group, for example, by palladium catalyzed vinylation.

Illustrative examples of suitable aryls include but are not limited to anthracenyl, fluorenyl, napthyl, phenyl, phenanthracenyl, and pyrenyl. Ar¹, Ar², and Ar³ each may include from one to five functional groups and may be optionally substituted with one or more moieties selected from the group consisting of halide(Cl, Br, I or F), C₁-C₂₀ alkyl, C₂-C₂₀ alkenyl, C₂-C₂₀ alkynyl, C₁-C₂₀ alkoxy, and aryl. Examples of suitable functional groups include but are not limited to: hydroxyl, thiol, thioether, ketone, aldehyde, ester, ether, amine, imine, amide, nitro, carboxylic acid, carbonate, isocyanate, carbodiimide, carboalkoxy and carbamate. These functional groups may be either substituted or unsubstituted and can be selected from the group consisting of OR¹, Cl, Br, I or F; NR¹R²; C(O)OR1; C(O)NR¹R²; NR¹C(O)R2; NO₃; N═C═O; C═N═O; NR¹C(O)NR¹R²; SR¹; C(O)R¹; OC(O)R¹; C₁ to C₂₀ alkyl; C₂ to C₂₀ alkenyl; C₂ to C₂₀ alkynyl; and aryl, wherein R¹, R² and R³are H, C¹ to C₂₀ alkyl, C₂ to C₂₀ alkenyl or C₂ to C₂₀ alkynyl.

Schemes 1 and 2 are two examples of preferred methods of forming a monobrominated triarylamine compound.

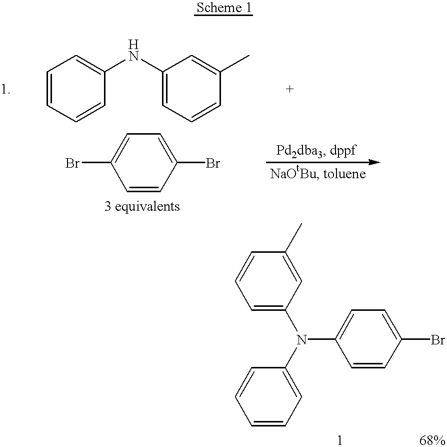

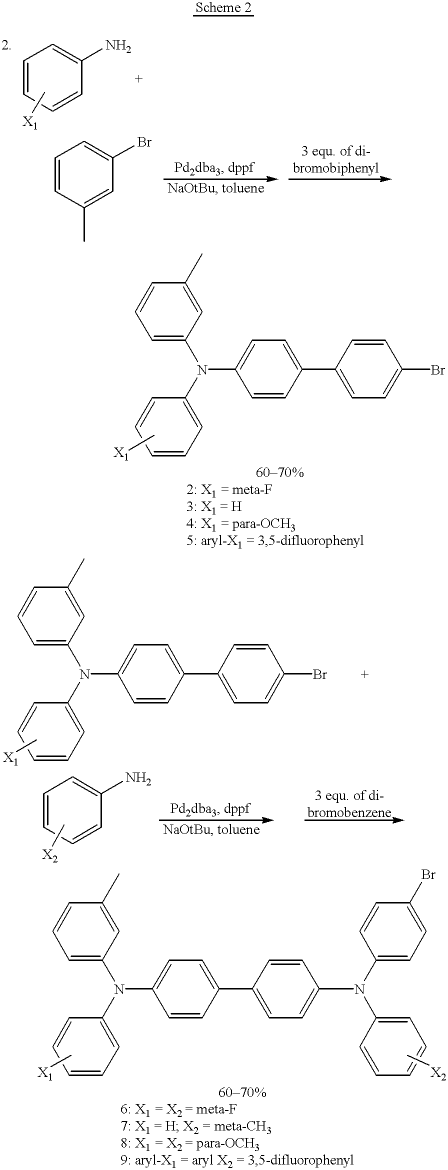

Scheme 2 depicts the reactions of four different starting materials wherein X₁ and X₂ symbolize different substituen patterms of the phenyl ring each one of hydrogen meta-F, meta-CH₃, para-OCH₃ and 3,5-difluoro.

The resulting monobrominated triarylamine compounds, 1, 6-9, are transformed into polymerizable monomers suitable for the practice of the present invention by palladium catalyzed vinylation. This protocol is illustrated by Scheme 3.

Another example of a route toward monomers 10-14 involves substitution of the bromine in the bromo derivative by an aldehyde group via lithiation and quenching with dimethylformamide, followed by reaction of the aldehyde with the appropriate Wittig reagent or titanium reagent (Pine, S. Org React 43:1 (1998)) to form the vinyl group

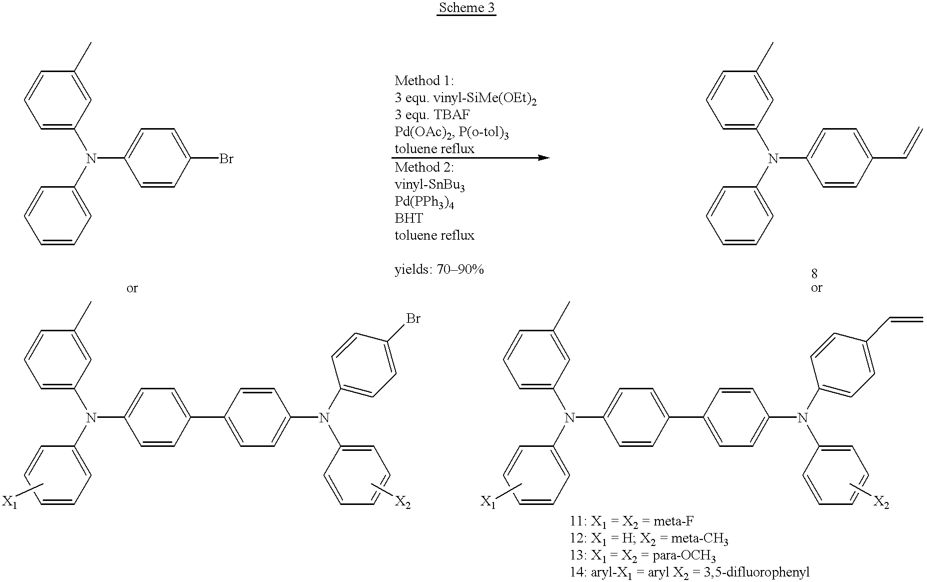

### Polymer Synthesis

The resulting monomers 10-14 are polymerized, for example, by anionic polymerization at −78° C. using n-butyllithium as an initiator and THF or THF/toluene as solvent. Scheme 4 depicts this polymerization reaction. Alternatively, the monomers are polymerized by radical polymerization, according to the following process:

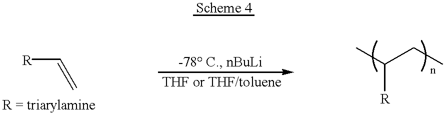

The resulting polymer products are:

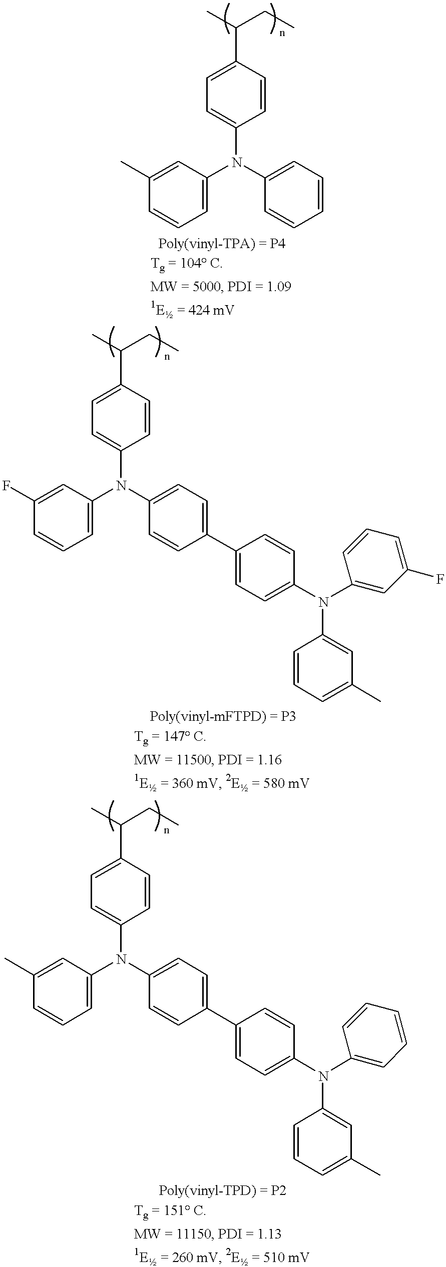

wherein T_{g} is the glass transition temperature; PDI is the polydispersity index determined by gel permeation chromatography in methylene chloride relative to monodisperse polystyrene standards; MW is the molecular weight as determined by gel permeation chromatography in methylene chloride relative to monodisperse polystyrene standards; and E1/2 is the redox potential by cyclic voltammetry in methylene chloride against ferrocenium/ferrocene.

In addition to homopolymers, copolymers may be prepared by polymerizing more than one monomer in the same reaction. Similarly, block copolymers may also be prepared by polymerizing individual monomers sequentially.

During the polymerization reactions, a copolymer bearing a crosslinkable functional group may also be added as a reactant to provide crosslinking sites in the polymer product. After the initial polymerization reaction, the resulting polymer may be crosslinked by the internal reactions of the copolymer functional groups with each other. Alternatively, a difunctional crosslinking additive may be used. In a preferred embodiment, the monomer is trimethoxyvinylsilane. This introduces trimethoxysilyl groups into the polymer, which cross-link on hydrolysis, forming Si—O—Si bonds. They can also form covalent bonds with the conducting glass through reaction with surface O—Si.

All five of the above polymers are soluble in organic solvents and thermally stabile up to 400° C. as analyzed by thermal gravimetric analysis. The glass transition temperatures were determined by differential scanning calorimetry (“DSC”).

### Use of the Inventive Polymers in LED devices

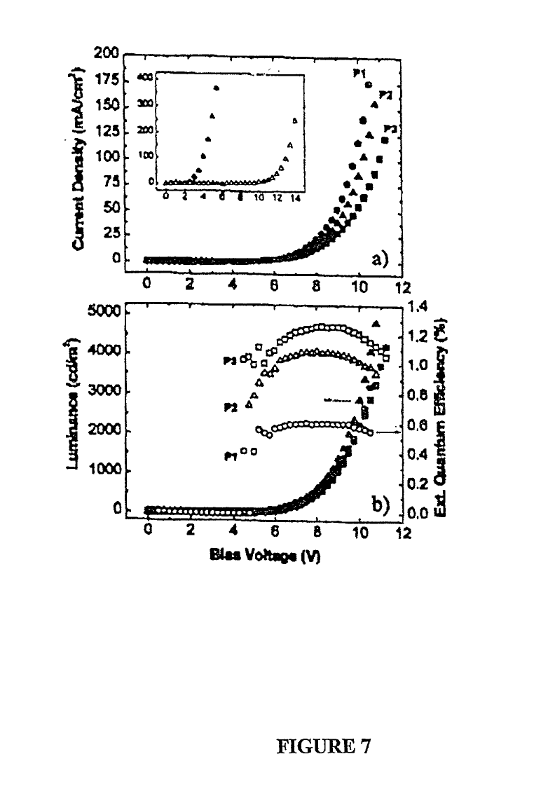

To compare the current-injection and transport properties of spin-coated polymer TPD (P2) versus thermally evaporated, small-molecule TPD, we prepared single-layer devices on ITO with an aluminum cathode. The inset to FIG. 7 shows that the turn-on voltage for the polymer P2 device is approximately 8V lower than for the small-molecule TPD device. We attribute this to a difference in the interfacial contact with ITO. Spin-coating of the polymer planarizes the rough ITO surface (2-3 nm RMS), and provides smooth, pinhole free films. When polymers P1-P3 are used as the HTL in an OLED, good interfacial contact with the ITO results in low leakage currents and a low operating-voltage. We emphasize that our deposition chamber has a small source-to-sample distance and a fixed, non-rotating sample holder; more sophisticated deposition systems are likely to yield better film coverage. However, this data illustrates the importance of the morphology at the organic-ITO interface for the hole injection into the OLED.

Two-layer LEDs have been prepared on ITO using the polymers P1-P5 as hole transport materials, Alq₃ as emitter and Mg as a cathode. The device shows typical Alq₃ emission (Tang, C. et al. Appl Phys Lett 51:913 (1987)), resulting in green LEDs with a peak emission of 525 nm. The data is summarized in the following Table:

TABLE 1
Device Characteristics versus Redox Potential of the Hole-transporting
Polymer for the Devices ITO/HTL/Alq₃/Mg

| | | | max. ext. quant | |
|---|---|---|---|---|
| | | Current | efficiency | |
| HTL | ¹E1/2^{a} | Density | (% photons/e⁻) | light output at |
| Polymer | (mV) | at 9 V | mA/cm² | 10 V (cd/m²⁾ |
| P1 | 150 | 53.4 | 0.61 | 2300 |
| P2 | 280 | 39.7 | 1.09 | 2900 |
| P3 | 390 | 28.7 | 1.25 | 3700 |
| P4 | 435^{b} | 27.4 | 1.22 | 1800 |
| P5 | 490 | 15.4 | 1.00 | 1000 |

^{a}¹E1/2 = E1/2(M⁺/M) determined by cyclic voltammetry in methylene chloride solution versus ferrocenium/ferrocene.
^{b}Irreversible redox potential estimated from (Eₒₓ + E_{red})/2.

The maximum external quantum efficiency increases substantially as the redox potential becomes more positive (compare P1, P2 and P3). Thus, this study suggests that higher external quantum efficiencies can be achieved with hole-transporting materials which are less electron rich than the commonly used TPD. An optimum value for the HTL redox potential appears to exist around 400 mV versus ferrocenium/ferrocene (P3).

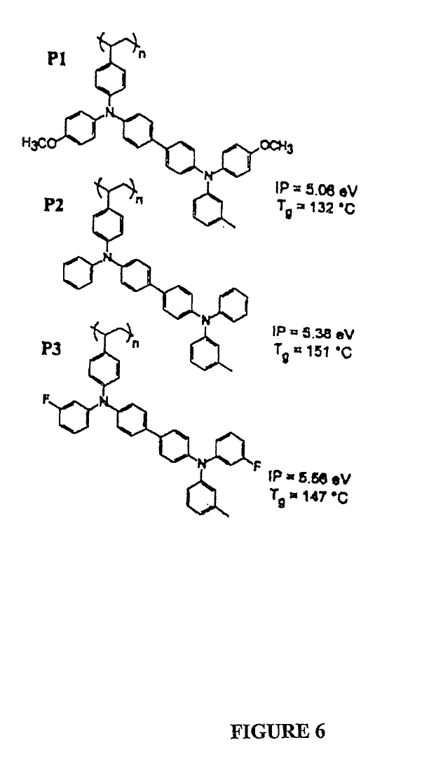

A series of functionalized polymers with triphenyldiamine (TPD) derivative side-groups was used as the hole-transporting layer (HTL). The IP of TPD has been determined as 5.38 eV by ultraviolet photoelectron spectroscopy (Anderson, J. et al. J Amer Chem Soc 1998 120:9646). This value can be systematically decreased (shifted toward the vacuum level) by adding an electron-donating moiety, such as p-OCH₃, or increased (shifted further from the vacuum level) by adding an electron-withdrawing moiety, such as m-F. This principle is demonstrated by the three polymer TPD derivatives shown in FIG. 6, P1-P3, that have an IP that ranges from 5.06 eV to 5.56 eV. In this study, we used polymers P1-P3 as the HTL in double-layer OLEDs with a thermally evaporated emission layer of either pure 8-hydroxyquinoline (Alq₃) (1P=5.93 eV), or Alq₃ doped with quinacridone.

FIG. 7 shows current density, luminance, and external quantum efficiency versus applied voltage for double-layer OLEDs using polymers P1-P3 as the HTL, Alq₃ as the emission layer, and Mg as a cathode. The emission spectra of the three devices were identical and exhibited the characteristic Alq₃ emission peak at approximately 525 nm. FIG. 7a shows that the operating-voltage required to drive a given current increases as the IP of the HTL is increased. FIG. 7b shows that the external quantum efficiency increases as the IP of the HTL is increased.

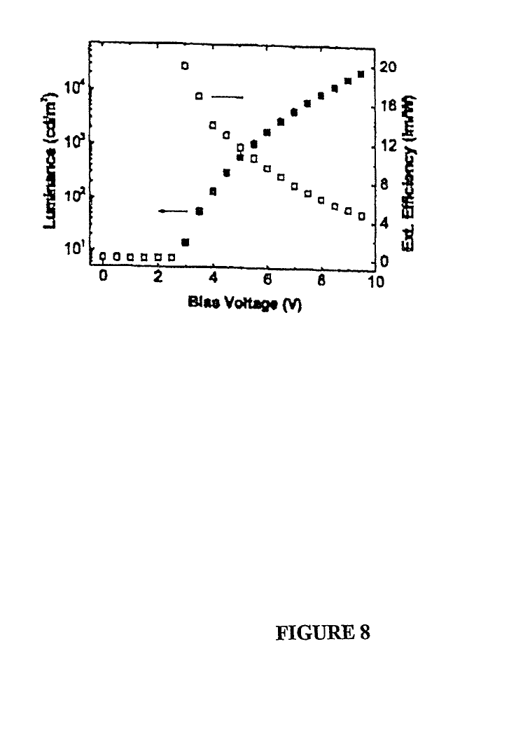

These same trends were also seen in optimized devices which included doping the Alq₃ emission layer with quinacridone and replacing the Mg cathode with a bilayer LiF/Al cathode (Tabbour, G. et al. Appl Phys Lett 1997 71:1762). FIG. 8 shows the luminance and luminous efficiency versus applied voltage for an optimized device using polymer P3 as the HTL. At an applied voltage of 3.0 V, the luminance is 15 cd/m², and the luminous efficiency is 20 lm/W (corresponding to approximately 4.5% external quantum efficiency). At an applied voltage of 4.0 V, the luminance is 135 cd/m², and the luminous efficiency is 14 lm/W.

We find that the most likely explanation for the trend in the OLED efficiencies is that increasing the IP of the HTL reduces the rate of hole injection from the ITO anode and creates a better balance between the number of holes and electrons in the device. The trend in the current density at 9 volts shown in FIG. 7a and Table 1 demonstrates that the number of injected majority carriers, generally thought to be holes, decreases as the IP of the HTL is increased. Another possible explanation for the trend in the efficiencies is that a ‘cross-reaction’ occurs at the interface between the HTL and the emission layer to produce luminescence. Electrogenerated chemiluminescence experiments carried out in solution between positively charged TPD molecules and negatively charged Alq₃ molecules have been shown to produce Alq₃ luminescence (Anderson, J. et al. 1998 J Amer Chem Soc 120:9646) The efficiency of this luminescence was shown to increase as the IP of the TPD derivative was increased, resulting from the increased driving force of the reaction. However, we do not attribute the trend in the OLED efficiencies to this mechanism. Complementary results show that devices in which a layer of thermally evaporated p-OCH₃-TPD, corresponding to polymer P1, has been inserted between the hole transport polymer P3 and the emission layer do not result in a decreased efficiency, as would be expected if the cross-reaction mechanism is important in the device operation. Therefore, we conclude that the cross-reaction is not the dominant mechanism of light emission in these devices. We also consider that the hole mobilities of the three polymer P1-P3 may differ because of additional dipole-disorder introduced by the side-groups. Lastly, it has been shown that exciplex formation between the HTL and the emission layer reduces the device efficiency (Tamoto, N. et al. Chem Mater 1998 9:1077), however, we find no evidence of exciplex emission in these devices.

### Monomers comprising Cyclic Olefins

In another set of experiments according to another embodiment of the invention, the monomers of the present invention comprise a triarylamine component having the structure of Formula I, a linker component, and a cyclic olefin that is capable of undergoing a ring-opening metathesis polymerization (ROMP) reaction.

The linker component may be any suitable moiety that is capable of bridging the triarylamine component to the cyclic olefin component. Illustrative examples of suitable linkers include C₁-C₂₀ alkyl, C₂-C₂₀ alkenyl, C₅-C₈ cycloalkyl, and aryl. The linker can comprise ester, ether, amide or other suitable functional groups.

The cyclic olefin component is any cyclic olefin that is capable of undergoing ring opening metathesis polymerization. Illustrative examples of suitable cyclic olefins include norbornene, norboranadiene, cyclopentene, dicyclopentadiene, cyclobutene, cycloheptene, cyclooctene, 7-oxanorbornene, 7-oxanorbornadiene, and cyclododecene.

In preferred embodiments, the combination of the linker and cyclic olefin components has the general Formula II

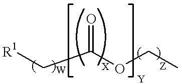

wherein R¹ is a cyclic olefin, x and y are either zero or 1, and, w and z are zero or any positive integer. In more preferred embodiments, R¹ is selected from one of the following:

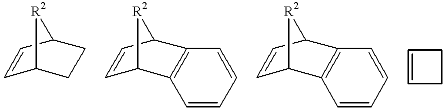

wherein R² is selected from the group consisting of CH₂, C-alkyl, C-dialkyl, O, N-alkyl and NH. In especially preferred embodiments the triarylamine component has the structure of Formula I: Ar¹, Ar², and Ar³ are each independently either unsubstituted phenyl or substituted phenyl; R¹ is an unsubstituted or a substituted norbornene; w, x, and y are either zero or 1; and z is 0 to 18. In the most preferred embodiments, w, x, and y are either zero or 1, and z is less than 5.

Moreover, any combination of the triarylamine, linker, and cyclic olefin components may be either further substituted with one or more substituents selected from the group consisting of halide, C₁-C₂₀ alkyl, C₂-C₂₀ alkenyl, C₂-C₂₀ alkynyl, C₁-C₂₀ alkoxy, and aryl, or further include one or more functional groups. Examples of suitable functional groups include but are not limited to: hydroxyl, thiol, thioether, ketone, aldehyde, ester, ether, amine, imine, amide, nitro, carboxylic acid, disulfide, carbonate, isocyanate, carbodiimide, carboalkoxy, carbamate, and halogen.

For the purposes of clarity, the practice of the present invention will be specifically illustrated with reference to a series of particularly preferred monomers wherein triarylamines are linked via either an ether or ester functionality to norbornenes.

As illustrated by Scheme 5, an essential step of the monomer synthesis is the assembly of a suitably functionalized triarylamine moiety through Pd-catalyzed coupling of a substituted bromobenzene with m-tolylphenylamine.

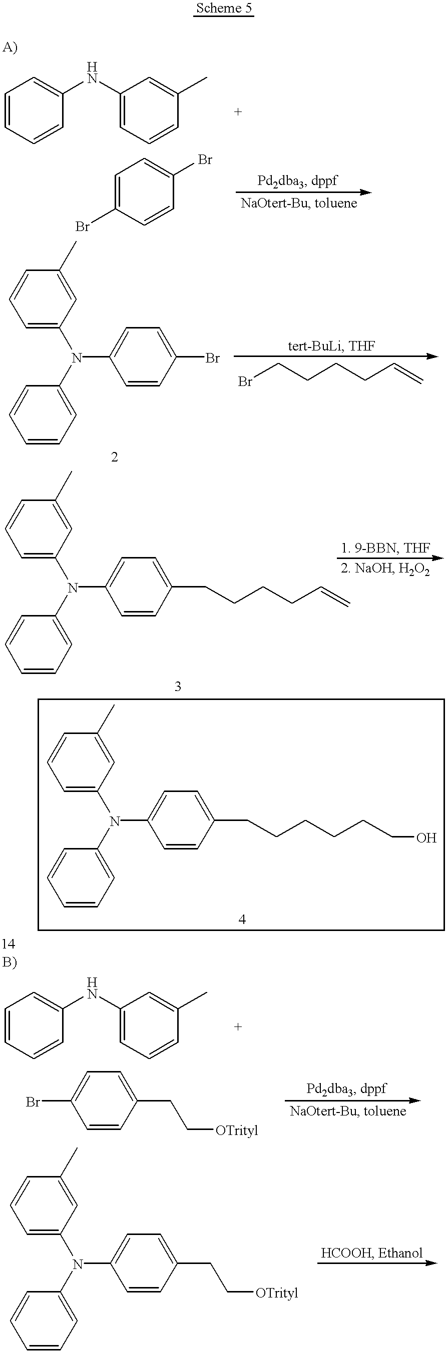

Using the chemistry developed by Buchwald and Hartwig, the three different triarylamines 16, 17, and 19 were obtained in yields of between about 60% to about 90%.

Alkylation of 1-bromo-4-(m-tolylphenylamino)benzene 1 with 6-bromohexene followed by reaction with 9-borabicyclo[3.3.1]nonane (“9-BBN”) afforded compound 16. Compound 17 was prepared from 4-bromophenethanol and compound 19 was obtained via Pd-coupling of m-bromoanisidine to m-tolylphenylamine. Triarylamine alcohol derivatives 16, 17, and 19 were condensed with norbornene derivatives to form monomers having either ester or ether linkages. So that experimental results from these inventive ester and ether monomers may be directly comparable with each other, meta-substituted phenol 19 was made instead of the para-substituted counterpart since a para-alkoxy-substituent would significantly alter the oxidation potential of the triarylamine. As shown by Scheme 6, the ester monomers 20, 21 and 22 have been synthesized from the alcohols 16, 17 and 19.

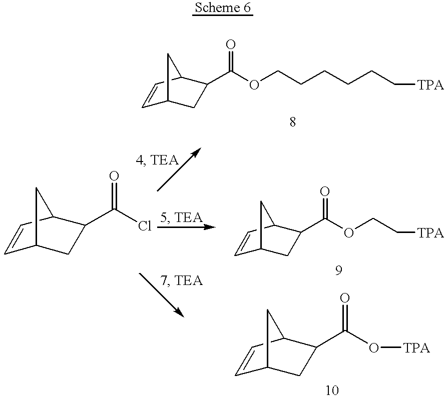

The less polar ether monomers were prepared by reactions shown by Scheme 7.

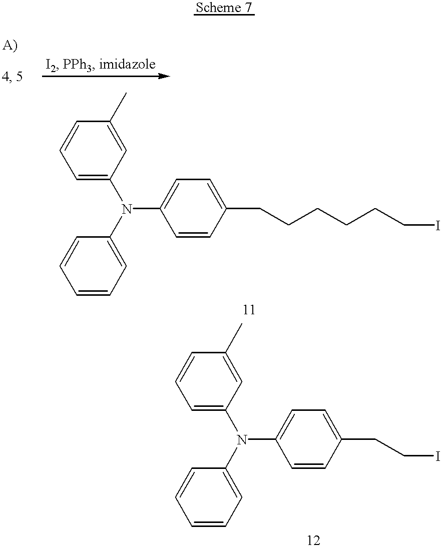

Compound 19 may be readily transformed to ether monomer 26 by direct condensation with norborn-2-ene-5-methanol. In contrast, compounds 16 and 17 were transformed to the corresponding iodides 23 and 24 before the reaction

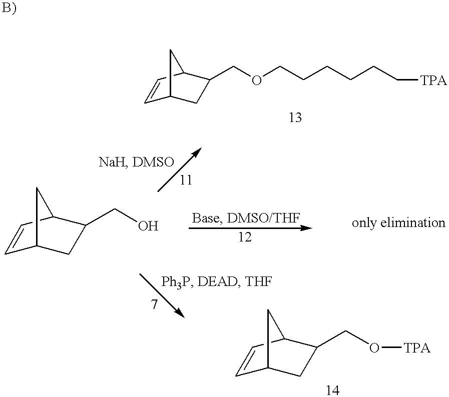

with norborn-2-ene-5-methanol. In the case of compound 23, the desired product 25 was isolated in 22% yield along with the elimination product 10. In the case of compound 24, only 1-vinyl-4-(m-tolylphenylamino)benzene was obtained in 60% yield. Altering reaction conditions did not substantially improve the results. For example, different solvents and lower reaction temperatures did not appreciably improve the yield of either ether product. In addition, changing the base also had no effect on the ratio of ether formation to elimination product. Finally, reacting alcohols 16 and 17 with norborn-2-ene-5-methyliodide was also tried but resulted in decomposition.

As a result, the ester monomers 20, 21, and 22, and ether monomers 25 and 26 were further characterized. Because the only difference between the ester monomers 20, 21 and 22, is the number of —CH₂— linkages between the ester moiety and the triarylamine moiety, these monomers will also be referred to as the C₆, C₂, and C₀ ester monomers. Similarly, ether monomers 25 and 26 will be referred to as C₆ and C₀ ether monomers based upon the number of —CH₂— groups between the ether and the triarylamine moiety.

### Polymerization of Cyclic Olefin Monomers

The cyclic olefin monomers were polymerized by ring opening metathesis polymerization (ROMP) Although only homopolymers were made, the detailed experimental protocols in the Experimental Section may be readily adapted by those skilled in the art to form copolymers and block polymers using the inventive monomers. The initiator used for the reaction, LₓMCH=CHR, was compound 27, since it has been found to be remarkably tolerant towards the presence of functional groups and generally results in living polymerization.

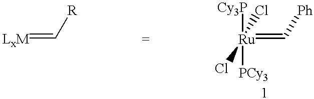

TABLE 2
Polymerization Results

| polymer | Mₙ^{a} | PDI^{a} |
|---|---|---|
| poly-20 | 48 000 | 1.22 |
| poly-21 | 38 000 | 1.16 |
| poly-22 | 46 000 | 1.13 |
| poly-25 | 62 000 | 1.22 |
| poly-26 | 58 000 | 1.17 |

^{a}Determined by gel permeation chromatography in CH₂Cl₂ relative to monodispersed polystyrene standards.

The general structure of the hole-transporting polymers is shown below.

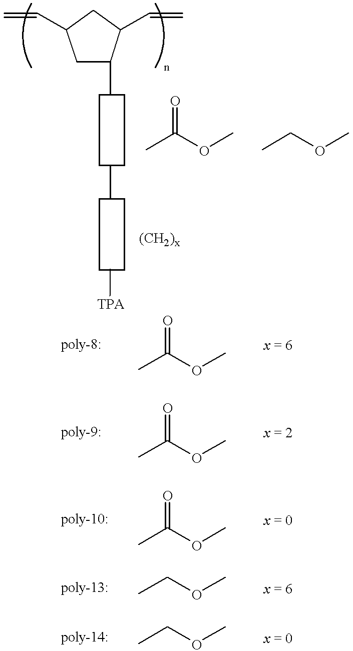

As previously observed with liquid crystalline ROMP polymers, the glass transition temperature, T_{g}, decreases as the number of —CH₂— groups in the linker compound increases (resulting in the higher mobility of the triarylamine moiety). Moreover, as Table 2 illustrates, the T_{g} of the ester polymers was found to be significantly higher than their ether counterparts.

TABLE 3
Glass Transition Temperatures for the
Triarylamine Substituted Poly(norbornenes)

| —COO— | | —CH₂—O | |
|---|---|---|---|
| polymer | T_{g}(° C.) | polymer | T_{g}(° C.) |
| poly-20 | 37.6 | poly 25 | 23.4 |
| poly-21 | 72.6 | | |
| poly-22 | 84.0 | poly-26 | 68.3 |

The inventive polymers were crosslinked by exposing the polymers to UV-light. For thin films, irradiation with a 150 W Hg:Xe lamp for 1 hour caused the films to become completely insoluble in organic solvents. Addition of a sensitizer was not necessary and did not shorten the time needed for crosslinking. The UV-irradiated films remain colorless, transparent and retain their blue fluorescence.

### Fabrication of Light Emitting Devices

Because all of the studied polymers had good solubilities in organic solvents, spin casting the polymers from chlorobenzene yielded uniform thin films. Although thinner HTL results in decreased device operating voltage, the external quantum efficiency can start to decrease if the HTL gets too thin. This effect is illustrated by the data of Table 4.

TABLE 4
ITO/poly-26 Alq₃/Mg: Dependence of the Device Performance
on the Thickness of the Hole Transport Layer

| thickness of | | max. ext. | | |
|---|---|---|---|---|
| the | operating | quantum eff. | max. light | max. ext. |
| HTL-film | voltage | (% photons/ | output | power |
| (nm)^{a} | (V)^{b} | electron) | (cd/m²) | eff. (Lm/W) |
| 30 | 5.25 | 0.81 | 1690 @ 11 V | 1.21 |
| 20 | 4.25 | 0.77 | 2580 @ 8 V | 1.30 |
| 15 | 3.25 | 0.62 | 3150 @ 7 V | 1.23 |

^{a}Determined by TINCOR alpha-step profilometer.
^{b}Light output at this voltage equals 5 cd/m².

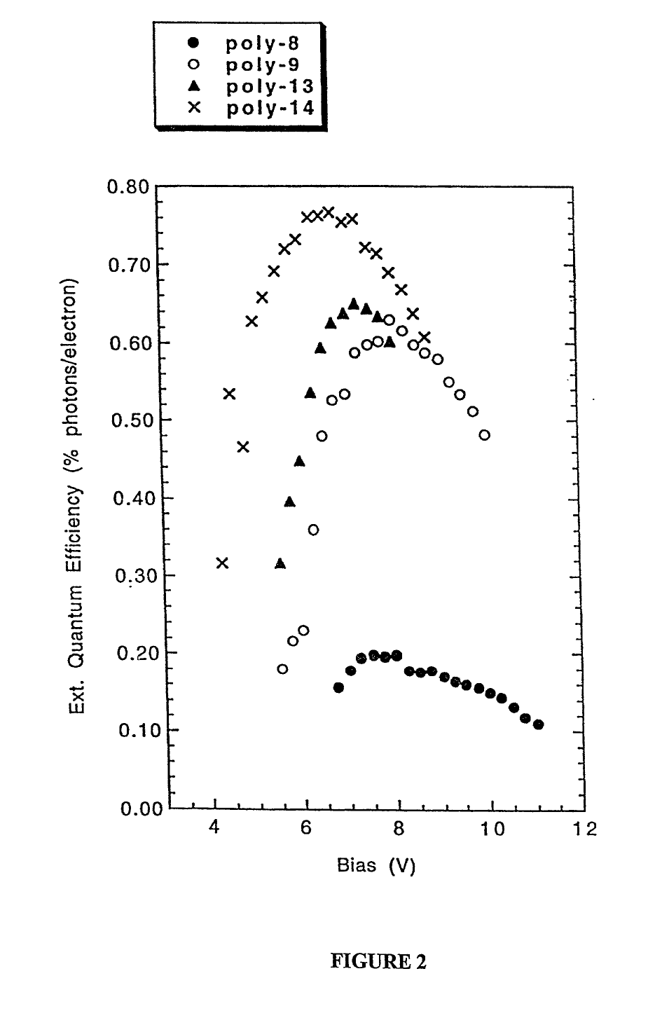

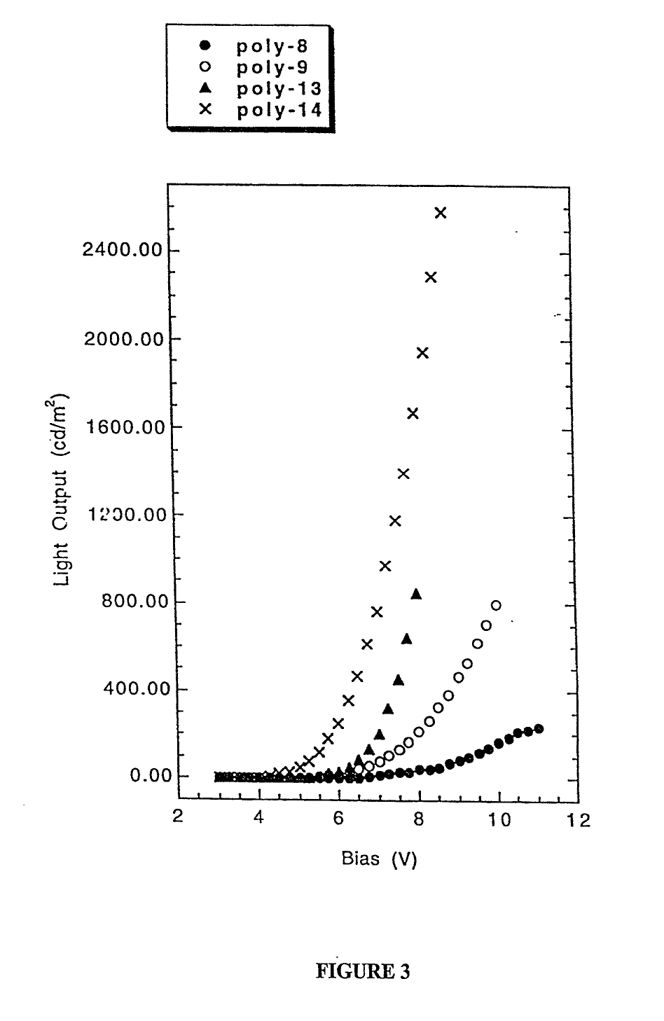

A thickness of 20 nm for the HTL film, which showed the highest external power efficiency, was chosen for the remaining set of experiments. Table 5 and FIGS. 2-5 summarize the device data for the hole-transporting poly(norbornenes).

TABLE 5
ITO/poly(norbornene)-TPA/Alq₃/Mg: Device
Performance for Different Hole-Transporting Polymers

| | | | Max. ext. | | max. |
|---|---|---|---|---|---|
| | | | quantum | | ext. |
| | | operating | eff. (% | max. light | power |
| | | voltage | photons/ | output | eff. |
| HTL-polymer | | (V)^{a} | electron) | (cd/m²) | (Lm/W) |
| —COO— | poly-20 | 6.75 | 0.20 | 240 @ 11 V | 0.26 |
| | poly-21 | 5.50 | 0.63 | 800 @ 10 V | 0.84 |
| | poly-22 | (8)^{b} | (0.42)^{b} | (1030 @ | (0.54)^{b} |
| | | | | 14 V)^{b} | |
| —CH₂—O— | poly-23 | 5.50 | 0.65 | 850 @ 8 V | 0.96 |
| | poly-26 | 4.25 | 0.77 | 2580 @ 8 V | 1.30 |
| x-linked | poly-26 | 5.25 | 0.37 | 880 @ 9 V | 0.61 |

All data refers to 20 nm thick HTL films. Crosslinking of poly-26 was achieved by UV-irradiation after spin casting on ITO.
^{a}Light output at this voltage equals 5 cd/m².
^{b}Degradation interfered with measurement.

All of the studied polymers exhibit high quantum efficiencies. The small structural differences between the five polymers have a large impact on the device performance, showing that reducing the polarity and length of the CH₂ linker between the ether/ester functionality and the cyclic olefin greatly improves the characteristics (compare poly-20 (C₆/ester) to poly-26 (C₀/ether)).

Poly-22 (C₀/ester) decomposed rapidly under device operating conditions. Separation of the carbonyl group from the triarylamine functionality by an alkyl segment results in increased stability of the device (poly-21, poly-20). The ether polymers poly-25 and poly-26 show the best stabilities, presumably since they lack the carbonyl group as a reaction center, thus reducing the number of possible decomposition pathways. Substitution of the ester functionality by the less polar ether linkage causes the external quantum efficiency to increase and the operating voltage to decrease significantly. In the case of poly-25 and poly-20, a threefold increase in external quantum efficiency has been achieved by substituting carbonyl groups with tile non-polar methylene groups.

Based on disorder formalism developed by Bässler and Borsenberger the hole mobilities in the less polar polymers, that is polymers with linkers containing an ether functionality, should be higher. The disorder model assumes that the charge transport occurs through hopping between localized electronic states, which show a Gaussian-shaped distribution. According to the model, energetical disorder, e.g. the presence of several functional groups with different polarities, results in broadening of the distribution of states and, consequently, in lower charge mobilities. Thus, the results on two-layer devices using a hole transport layer and Alq₃ as an emitting layer suggest that the quantum efficiency can be improved and the operating voltage decreased by increasing the hole mobility of the HTL. One caveat of that analysis is the possible influence of the polymer structure on the position of the highest occupied molecular orbital (HOMO) of the triarylamine moieties. The relative position of the energy levels of the hole transport and the light-emitting moieties is expected to affect the performance of two-layer devices as well. Independent mobility measurements by time-of-flight experiments and energy level determination will provide more information.

The longer alkyl linking region (the number of CH₂ groups between the ester/ether functionality and the triarylamine moiety) resulted in an increase in the number of degrees of freedom available to the triarylamine side groups. Previously, it has been found that for carbazole containing polymers, increased mobility of the hole-conducting side groups enhances hole mobility.

However, in the inventive ester and ether systems, a decrease in efficiency and an increase in operating voltage was found with increasing —CH₂— linker length (poly-20 vs. poly-21 and poly-25 vs. poly-26). In contrast to previously reported results, the polymers with the shortest linkers showed best performance.

Without being bound by theory, it is believed that if side group mobility promotes hole transport in the inventive systems, this influence is overcompensated by the fact, that longer alkyl linkers also correspond to more insulating matter of the hole-transporting functionalities. This results in lower density around the triarylamines which in turn results in less efficient charge transport and decreased device performance.

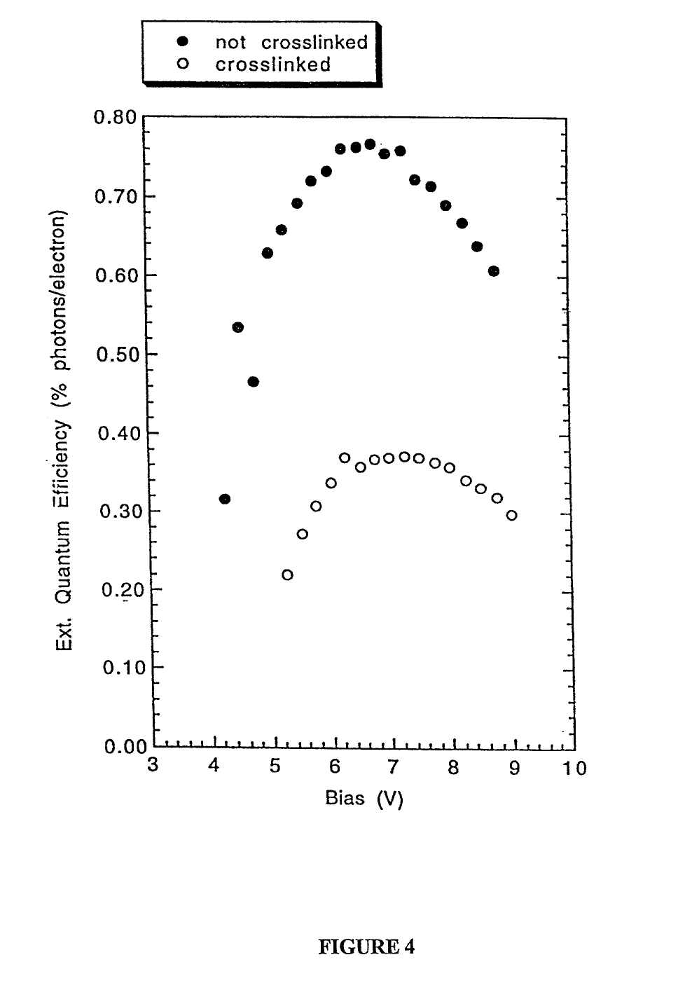

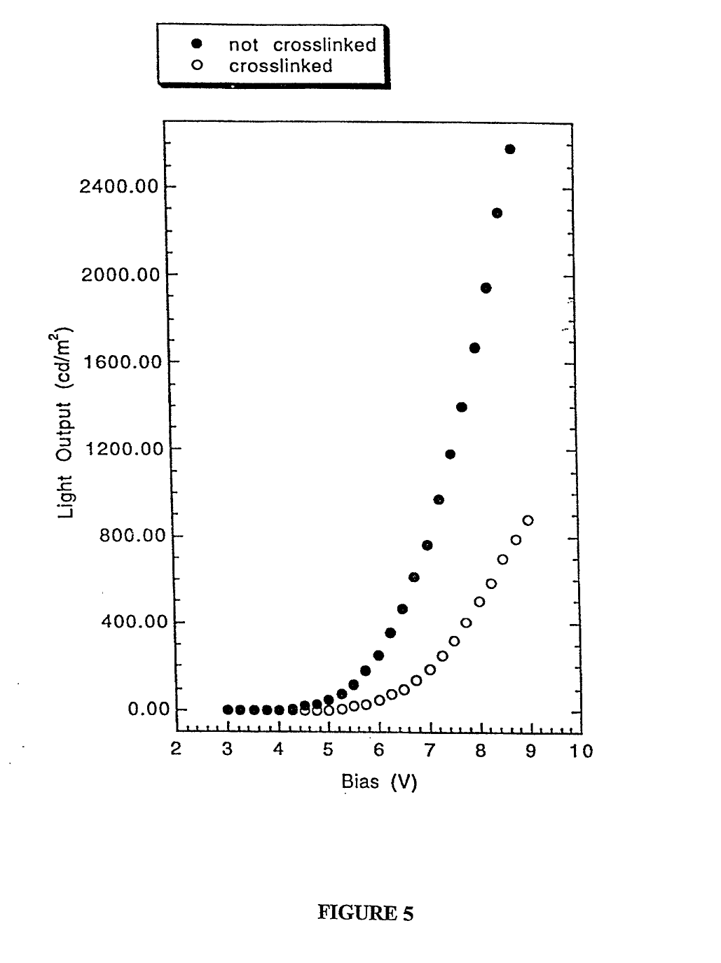

All of the studied polymers were crosslinked by a simple procedure, which did not require addition of other reagents or removal of byproducts. Crosslinked devices show poorer performance relative to the ones with the original soluble films (see Table 5, FIGS. 4 and 5). Possible explanations are partial decomposition of the polymers from exposure to UV and decreased film quality as a consequence of slight volume changes upon crosslinking. Decreased mobility of the triarylamine side groups may also contribute to a reduced charge transport efficiency. However, a crosslinkable HTL allows the fabrication of two-layer devices with a spin casted polymer as its emitting layer.

### EXPERIMENTAL PROCEDURES

### General Methods

All syntheses were carried out under argon, which was purified by passage through columns of BASF R-11 catalyst (Chemalog) and 4 Å molecular sieves (Linde). NMR spectra were recorded on GE QE-300 Plus (300 MHz for ¹H; 75 MHz for ¹³C) spectrometer. Gel permeation chromatograms were obtained on a HPLC system using an Altex model 110A pump, a Rheodyne model 7125 injector with a 100 μL injection loop, American Polymer Standards 10 micron mixed bed columns, a Knauer differential refractometer and CH₂Cl₂ as eluent at a 1.0 mL/min flow rate. Cyclic voltammetry was conducted using a glassy carbon working electrode, a platinum auxiliary electrode and a AgCl/Ag pseudo-reference electrode in 0.1 M solutions of tetrabutylammonium hexafluorophosphate in methylene chloride. Redox potentials were referenced to the ferrocene/ferrocenium couple (E_{1/2} (ferrocenium/ferrocene)=0 V). Differential scanning calorimetry was carried out on a Perkin-Elmer DSC-7 with a scan rate of 10° C./min. Thermal gravimetric analysis was performed under nitrogen at a heating rate of 10° C./min using a Shimadzu TGA-50 device and aluminum pans. UV-VIS spectra were recorded using a Hewlett-Packard HP 8453 spectrometer. High resolution mass spectra were provided by the Southern California Mass Spectrometry Facility (University of California at Riverside) and by Mass Spectrometry Facility of University of California at Los Angeles. Elemental analyses were performed by Midwest Microlabs.

### Materials

Alq₃, quinacridone and TPD were obtained commercially (Aldrich) and purified by sublimation techniques. Methylene chloride used in polymerization experiments was distilled from CaH₂ and degassed by freeze-pumping the liquid several times. Toluene and tetrahydrofuran were distilled from Na/benzophenone. Methylene chloride used in cyclic voltammetry measurements was dried and degassed by passage through drying columns (Pangburn, A. et al. Chem Mater 11(2):399-407 (1996)). 1-bromo-4-(m-tolylphenylamino)benzene (1) was prepared as previously reported (Bellmann, E. et al. Chem Mater 10:1668 (1998)). All other reagents and starting materials were purchased from Aldrich Chemical Company or Strem Chemicals and used as received unless otherwise noted.

Preparation of 4-bromo-4′-(m-tolyl-p-methoxyphenylamino)biphenyl (4)

Tris(dibenzylideneacetone)dipalladium(0) (Pd₂dba₃) (618 mg, 0.67 mmol), 1,1′-bis(diphenylphosphino)ferrocene (dppf) (561 mg, 1 mmol) and 3-bromotoluene (7.7 g, 45 mmol) were dissolved in 400 mL dry toluene and stirred for 15 min. Sodium tert-butoxide (5.2 g, 54 mmol) and p-methoxyaniline (5.5 g, 45 mmol) were then added. The reaction mixture was warmed to 100° C. for 3 h. Thereafter, 4,4′-dibromobiphenyl (42 g, 135 mmol) and sodium tert-butoxide (5.2 g, 54 mmol) were added and the reaction mixture heated to 100° C. for 16 h. The reaction mixture was partitioned between water and ether, and the aqueous layer was extracted with ether. The combined organic fractions were dried over MgSO₄, and the solvent evaporated under reduced pressure. Column chromatography (silica, hexanes) afforded 19.3 g (84%) of product 4. ¹H NMR (CD₂Cl₂) δ7.57-7.37 (m, 6H), 7.15-6.97 (m, 6H), 6.91-6.80 (m, 4H), 3.78 (s, 3H), 2.24 (s, 3H); ¹³C NMR (CD₂Cl₂) δ 157.1, 148.7, 148.3, 141.0, 140.2, 139.7, 132.8, 132.4, 129.6, 128.6, 128.1, 127.9, 124.9, 124.1, 122.7, 121.4, 121.1, 115.4, 56.0, 21.8; HRMS calcd. for C₂₆H₂₂⁸¹BrNO [M⁺]445.0885; found 445.0864; Anal. calcd. for C₂₆H₂₂BrNO: C 69.94, H 4.46, N 3.26. Found: C 69.69, H 4.49, N 3.15.

Preparation of 4-bromo-4′-(m-tolylphenylamino)biphenyl (3)

3 was prepared by analogy to 4 using aniline instead of p-methoxyaniline in 66% yield. ¹H NMR (CD₂Cl₂) δ7.58-7.53 (m, 2H), 7.49-7.43 (m, 4H), 7.29 (dt, J=2.1, 7.8 Hz, 2H), 7.19 (bd t, J=7.8 Hz, 1H), 7.14-7.03 (m, 5H), 6.98 (bd s, 1H), 6.92 (bd dt, 2H, J=1.8, 7.6 Hz, 2H), 2.24 (s, 3H); ¹³C NMR (CD₂Cl₂) δ 147.5, 147.4, 147.2, 139.3, 139.1, 133.0, 131.5, 129.0, 128.9, 127.9, 127.2, 125.1, 124.1, 123.9, 123.2, 122.7, 121.6, 120.5, 20.9; HRMS calcd. for C₂₅H₂₀⁸¹BrN [M⁺] 415.0759, found 415.0753; Anal. calcd. for C₂₅H₂₀BrN: C 72.47, H 4.87, N 3.38. Found: C 72.24, H 4.82, N 3.34.

Preparation of 4-bromo-4′-(m-tolyl-m-fluorophenylamino)biphenyl (2)

2 was prepared by analogy to 4 using m-fluoroaniline instead of p-methoxyaniline in 62% yield. ¹H NMR (CD₂Cl₂) δ 7.60-7.42 (m, 6H), 7.25-7.12 (m, 4H), 7.02-6.67 (m, 6H), 2.24 (s, 3H); ¹³C NMR (CD₂Cl₂) δ 165.7, 162.4, 150.2, 150.0, 147.6, 147.4, 140.2, 140.0, 134.9, 132.4, 130.9, 130.7, 129.9 128.8, 128.3, 126.7, 125.6, 125.1, 123.2, 121.6, 119.1, 110.5, 110.2, 109.5, 109.2, 21.8; HRMS calcd. for C₂₅H₁₉⁷⁹BrF₂N [M⁺]433.0664, found 433.0663; Anal. calcd. for C₂₅H₁₉BrFN: C 69.45, H 4.43, N 3.24. Found: C 69.66, H 4.45, N 3.28.

Preparation of 4-bromo-4′-(m-tolyl-3,5-difluorophenylamino)biphenyl (5)

5 was prepared by analogy to 4 using 3,5-difluoroaniline instead of p-methoxyaniline in 69% yield. ¹H NMR (CD₂Cl₂) δ 7.60-7.42 (m, 8H), 7.25-7.15 (m, 4H), 7.01 (bd m, 2H), 6.53 (m, 2H), 6.38 (m, 1H), 2.24 (s, 3H); ¹³C NMR (CD₂Cl₂) δ 165.9, 165,7 162.6, 162.4, 150.9, 146.8, 146.7, 140.4, 139.9, 136.0, 132.4, 130.0, 128.9, 128.4, 127.3, 126.4, 126.0, 123.8, 121.9, 121.7, 104.7, 104.6, 104.5, 104.3, 97.2, 96.8, 96.5, 21.8; HRMS calcd. for C₂₅H₁₈BrF₂N [M⁺]449.0583, found 449.0590; Anal. calcd. for C₂₅H₁₈BrF₂N: C 66.68, H 4.03, N 3.11. Found: C 66.36, H 4.00, N 3.11.

Preparation of 4-(m-tolyl-p-methoxyphenylamino)-4′-(p-methoxybenzyl-p-bromophenylamino)biphenyl (8)

8 was prepared by analogy to 4 from 4 and p-methoxyaniline followed by the addition of 1,4-dibromobenzene in 65% yield. Purification was accomplished by column chromatography on silica gel with hexanes followed by 20% toluene in hexanes. ¹H NMR (CD₂Cl₂) δ 7.41 (bd t, J=8.1 Hz, 4H), 7.29 (bd d, J=8.7 Hz, 2H), 7.06 (m, 10H), 6.87 (m, 8H), 3.78 (s, 6H), 2.24 (s, 3H); ¹³C NMR (CD₂Cl₂) δ 157.3, 156.9, 148.5, 147.9, 146.9, 141.1, 140.5, 139.6, 135.3, 134.0, 132.5, 129.5, 128.1, 127.9, 127.7, 127.6, 124.5, 124.3, 124.0, 123.7, 123.1, 121.0, 115.4, 115.3, 114.1, 56.0, 21.8; HRMS calcd. for C₃₉H₃₃⁸¹BrN₂O₂ [M⁺] 642.1705, found 642.1711; Anal. calcd. for C₃₉H₃₃BrN₂O₂: C 73.01, H 5.18, N 4.37. Found: C 72.82, H 5.15, N 4.31.

Preparation of 4-(m-tolylphenylamino)-4′-(m-tolyl-p-bromophenylamino)biphenyl (7)

7 was prepared by analogy to 4 from 3 and 3-aminotoluene followed by the addition of 1,4-dibromobenzene in 63% yield. Purification was accomplished by column chromatography on silica gel with hexanes followed by 20% toluene in hexanes. ¹H NMR (CD₂Cl₂) δ 7.50-7.40 (m, 4H), 7.35-7.30 (m, 2H), 7.28-7.21 (m, 2H), 7.18-7.00 (m, 9H), 6.98-6.85 (m, 8H), 2.24 (s, 6H); ¹³C NMR (CD₂Cl₂) δ 148.3, 148.1, 147.7, 147.6, 147.5, 146.9, 140.0, 139.8, 135.7, 134.8, 132.6, 129.7, 129.6, 129.5, 128.7, 127.8, 127.7, 126.0, 125.7, 125.6, 124.94, 124.87, 124.76, 124.5, 124.4, 123.3, 122.4, 122.2, 115.0, 21.8; HRMS calcd. for C₃₈H₃₁⁸¹BrN₂ [M⁺] 596.1650, found 596.1649; Anal. calcd. for C₃₈H₃₁BrN₂: C 76.63, H 5.25, N 4.70. Found: C 76.85, H 5.55, N 4.36.

Preparation of 4-(m-tolyl-m-fluorophenylamino)-4′-(-m-fluorophenyl-p-bromophenylamino)biphenyl (6)

6 was prepared by analogy to 4 from 2 and m-fluoroaniline followed by the addition of 1,4-dibromobenzene in 63% yield. Purification was accomplished by column chromatography on silica gel with hexanes followed by 10% ethyl acetate in hexanes. ¹H NMR (CD₂Cl₂) δ 7.52 (dd, J=8.4, 6.3 Hz, 4H), 7.41 (d, J=8.7 Hz, 2H), 7.28-7.12 (m, 8H), 7.07-6.93 (m, 5H), 6.90-6.65 (m, 5H), 2.24 (s, 3H); ¹³C NMR (CD₂Cl₂) δ 164.8, 161.6, 149.4, 149.3, 148.8, 148.6, 146.6, 146.2, 146.0, 145.5, 139.3, 135.7, 134.7, 132.1, 130.1, 130.0, 129.9, 129.8, 129.0, 128.7, 127.9, 127.8, 127.2, 125.8, 125.6, 124.8, 124.5, 124.4, 122.2, 118.5, 118.0, 115.5, 110.0, 109.6, 109.4, 109.1, 109.0, 108.8, 108.3, 108.0, 21.8; HRMS calcd. for C₃₇H₂₇⁸¹BrF₂N₂ [M⁺] 618.1305, found 618.1310; Anal. calcd. for C₃₇H₂₇BrF₂N₂: C 71.97, H 4.41, N 4.54. Found: C 72.13, H 4.81, N 4.73.

Preparation of 4-(m-tolyl-3,5-difluorophenylamino)-4′-(-3,5-difluorophenyl-p-bromophenylamino)biphenyl (9)

9 was prepared by analogy to 4 from 5 and 3,5-difluoroaniline followed by the addition of 1,4-dibromobenzene in 62% yield. Purification was accomplished by column chromatography on silica gel with hexanes followed by 20% toluene in hexanes. ¹H NMR (CD₂Cl₂) δ 7.67-7.62 (m, 2H), 7.58-7.49 (m, 4H), 7.34-7.11 (m, 8H), 7.02-6.93 (m, 3H), 6.86-6.80 (m, 1H), 6.53-6.31 (m, 4H), 2.24 (s, 3H); ¹³C NMR (CD₂Cl₂) δ 165.5, 165.3, 165.0, 164.9, 164.8, 150.8, 150.65, 150.5, 146.4, 145.8, 145.7, 140.3, 140.0, 136.4, 135.5, 132.7, 132.6, 130.4, 129.7, 129.2, 128.4, 128.0, 127.9, 127.8, 126.9, 125.9, 125.4, 123.4, 122.8, 121.3, 104.2, 104.1, 103.9, 103.8, 103.7, 98.0, 97.6, 96.6, 96.2, 95.9, 95.5, 95.1, 94.8, 21.8; HRMS calcd. for C₃₇H₂₅⁷⁹BrF₄N₂ [M⁺] 652.1135, found 652.1137; Anal. calcd. for C₃₇H₂₁BrN₂F₄: C 68.04, H 3.24, N 4.28. Found: C 68.17, H 3.44, N 4.11.

Preparation of 4-(m-tolyl-p-methoxyphenylamino)-4′-p-methoxyphenyl-p-vinylphenylamino)biphenyl (13)

Method 1: 8 (3 g, 4.67 mmol), palladium acetate (26.2 mg, 0.12 mmol) and tris(o-tolyl)phosphine were dissolved in 15 ml toluene. Diethoxymethylvinylsilane (2.25 g, 14 mmol) and tributylammoniumfluoride (21 mL of a 1M solution in tetrahydrofuran, 14 mmol) were added to the solution, and the reaction mixture was heated to 100° C. for 4 h. Method 2: 8 (3 g, 4.67 mmol), tetrakis(triphenylphosphine)palladium(0) (136 mg, 0.12 mmol) and 2,6-di-tert-butyl-4-methylphenol (2-5 mg) were dissolved in 25 mL toluene. Tributyl(vinyl)tin (1.8 g, 5.6 mmol) was added to the solution, and the mixture was heated to 100° C. for 3 h. Purification of the product was achieved through column chromatography (silica, 10% ethyl acetate in hexanes). The yields were 83% for method 1 and 92% for method 2. ¹H NMR (CD₂Cl₂) δ 7.46-7.38 (m, 4H), 7.30-7.20 (m, 2H), 7.16-6.97 (m, 12H), 6.94-6.89 (m, 6H), 6.66 (dd, J=10.8, 17.7 Hz, 1H), 5.63 (d, J=17.7 Hz, 1H), 5.13 (d, J=10.8 Hz, 1H), 3.78 (s, 6H), 2.24 (s, 3H); ¹³C NMR (CD₂Cl₂) δ 157.1, 156.9, 148.5, 148.3, 147.8, 147.6, 143.3, 141.1, 140.8, 139.6, 136.8, 134.9, 134.5, 134.2, 134.1, 131.7, 129.7, 129.5, 128.0, 127.9, 127.5, 124.5, 123.8, 123.6, 123.5, 123.4, 123.2, 122.8, 122.7, 122.5, 121.0, 115.4, 115.3, 112.1, 56.0, 21.8; HRMS calcd. for C₄₁H₃₆N₂O₂ [M⁺] 588.2777, found 588.2787; Anal. calcd. for C₄₁H₃₆N₂O₂: C 83.64, H 6.16, N 4.76. Found: C 83.74, H 6.52, N 4.63.

Preparation of 4-(m-tolylphenylamino)-4′-(m-tolyl-p-vinylphenylamino)biphenyl (12)

12 was prepared by analogy to 13 from 7 in yields of 64% for method 1 and 76% for method 2. Purification was accomplished by column chromatography on silica gel with 5% ethyl acetate in hexanes. ¹H NMR (CD₂Cl₂) δ 7.45 (dd, J=2.4, 8.7 Hz, 4H), 7.32-7.22 (m, 4H), 7.18-6.97 (m, 12H), 6.95-6.85 (m, 5H), 6.66 (dd, J=11.1, 17.7 Hz, 1H), 5.64 (d, J=17.7 Hz, 1H), 5.13 (d, J=11.1 Hz, 1H), 2.24 (s, 6H); ¹³C NMR (CD₂Cl₂) δ 148.3, 148.1, 148.0, 147.9, 147.4, 147.1, 139.9, 139.8, 136.7, 135.3, 135.0, 134.9, 133.5, 132.3, 129.7, 129.6, 129.2, 127.7, 127.5, 125.9, 125.7, 124.8, 124.4, 124.0, 123.2, 122.4, 122.2, 112.4, 21.8; HRMS calcd. for C₄₀H₃₄N₂ [M⁺] 542.2722, found 542.2728; Anal. calcd. for C₄₀H₃₄N₂: C 88.52, H 6.31, N 5.16. Found: C 88.53, H 6.58, N 4.98.

Preparation of 4-(m-tolyl-m-fluorophenylamino)-4′-(-m-fluorophenyl-p-vinylphenylamino)biphenyl (11)

11 was prepared by analogy to 13 from 6 in yields of 66% for method 1 and 92% for method 2. Purification was accomplished by column chromatography on silica gel with 20% toluene in hexanes. ¹H NMR (CD₂Cl₂) δ 7.53-7.45 (m, 4H), 7.36-7.26 (m, 2H), 7.22-7.04 (m, 9H), 6.93 (bd t, J=7.8 Hz, 3H), 6.87-6.62 (m, 7H), 5.67 (d, J=17.7 Hz, 1H), 5.18 (d, J=11.1 Hz, 1H), 2.24 (s, 6H); ¹³C NMR (CD₂Cl₂) δ 165.6, 162.4, 150.3, 150.1, 149.9, 149.8, 147.5, 147.2, 147.0, 146.6, 140.1, 136.6, 136.2, 136.0, 135.7, 130.6, 130.0, 129.8, 128.3, 128.0, 127.7, 126.5, 125.6, 125.4, 125.3, 125.1, 124.3, 123.0, 119.2, 118.8, 113.1, 110.6, 110.3, 110.2, 110.0, 109.9, 109.6, 109.3, 109.1, 109.0, 108.8, 21.8; HRMS calcd. for C₃₉H₃₀N₂F₂ [M⁺] 564.2377, found 564.2397; Anal. calcd. for C₃₉H₃₀N₂F₂: C 82.96, H 5.35, N 4.96. Found: C 82.78, H 5.43, N4.85.

Preparation of m-tolyl-(p-vinylphenyl)phenylamine (10)

10 was prepared by analogy to 13 from 1 in yields of 66% for method 1 and 89% for method 2. Purification was accomplished by column chromatography on silica gel with hexanes. ¹H NMR (CD₂Cl₂) δ 7.35-7.25 (m, 4H), 7.18 (bd t, J=7.8 Hz, 1H), 7.13-7.01 (m, 5H), 7.18-6.88 (m, 3H), 6.70 (dd, J=10.8, 17.7 Hz, 1H), 5.67 (d, J=17.7 Hz, 1H), 5.13 (d, J=10.8 Hz, 1H), 2.24 (s, 6H); ¹³C NMR (CD₂Cl₂) δ 147.75, 147.70, 147.6, 139.3, 136.3, 131.7, 129.3, 129.1, 127.0, 125.3, 124.3, 124.1, 123.4, 122.9, 121.8, 111.9, 21.8; HRMS calcd. for C₂₁H₁₉N [M⁺] 285.1512, found 285.1517; Anal. calcd. for C₂₁H₁₉N: C 88.38, H 6.71, N 4.91. Found: C 88.08, H 6.85, N 4.69.

Preparation of 4-(m-tolyl-3,5-difluorophenylamino)-4′-(-3,5-difluorophenyl-p-vinylphenylamino)biphenyl (14)

14 was prepared by analogy to 13 from 9 using method 2 in 78% yield. Purification was accomplished by column chromatography on silica gel with 20% toluene in hexanes. ¹H NMR (CD₂Cl₂) δ 7.62-7.51 (m, 6H), 7.43-7.37 (m, 2H), 7-29-7.13 (m, 6H), 7.05-6.96 (m, 3H), 6.92-6.75 (m, 2H), 6.57-6.34 (m, 4H), 5.86 (d, J=17.7 Hz, 1H), 5.34 (d, J=10.8 Hz, 1H), 2.24 (s, 6H); ¹³C NMR (CD₂Cl₂) δ 165.9, 165.7, 165.2, 165.0, 163.1, 162.8, 162.7, 162.5, 161.9, 161.7, 159.8, 159.6, 151.2, 151.0, 150.9, 146.8, 146.1, 144.8, 144.7, 144.6, 141.0, 140.4, 138.3, 136.8, 135.7, 131.4, 131.1, 130.0, 129.5, 128.7, 128.2, 128.1, 127.5, 127.3, 126.3, 125.8, 123.7, 121.6, 115.2, 104.4, 104.1, 98.2, 97.9, 96.9, 96.6, 96.2, 95.7, 95.4, 95.0, 21.8; HRMS calcd. for C₃₉H₂₈N2F₄ [M⁺] 600.2174, found 600.2188; Anal. calcd. for C₃₉H₂₄N₂F₄: C 77.99, H 4.03, N 4.68. Found: C 77.89, H 4.17, N 4.52.

General polymerization procedure:

Anionic Polymerization: The monomer (1.5 mmol, 500 mg−1 g) was dissolved in solvent mixture of 2 mL toluene and 0.2 mL THF. The solution was cooled to −78° C. and the polymerization was initiated through injection of n-butyllithium (0.075 mmol, 46.9 μL of a 1.6 M solution in hexanes). The polymerization was allowed to proceed for 1 h at −78° C. The reaction mixture was poured into methanol to precipitate the polymer. The polymers were purified by redissolving in methylene chloride and repricipitation into methanol several times and drying in vacuo. P1, P2, P3 and P4 were prepared using this procedure. In the case of P5, the monomer was dissolved in 5 mL THF and 3.075 mmol of n-butyllithium were added to initiate. During the purification of P5, an insoluble fraction was removed by filtration.

Radical Polymerization: A solution of the monomer (1 mol/L) and a radical initiator (0.1 mol/L) in benzene was heated to 80° C. for 48 h. The polymers are precipitated by reprecipitation as described above.

Copolymerization

Addition of 2-8 equivalents of trimethoxyvinylsilane to the solution described under “Radical Polymerization” results in incorporation of the trimethoxylsilane functionality into the polymer in amounts of 1-15%.

P1: 96% yield. ¹H NMR (CD₂Cl₂) δ 7.4 (bd), 7.1 (bd), 6.8 (bd), 6.5 (bd), 3.7 (bd), 3.4 (bd), 2.2 (bd, two overlapping signals), 1.6 (bd).

P2: 98% yield. ¹H NMR (CD₂Cl₂) δ 7.4 (bd), 7.1 (bd), 6.8 (bd), 2.3 (bd), 2.2 (bd), 1.6 (bd).

P3: 98% yield. ¹H NMR (CD₂Cl₂) δ 7.5 (bd), 7.2 (bd), 6.9 (bd), 6.5 (bd), 2.3 (bd), 2.2 (bd), 1.6 (bd).

P4: 96% yield. ¹H NMR (CD₂Cl₂) δ 7.2-6.5 (bd), 2.2 (bd, two overlapping signals), 1.6 (bd).

P5: 65% yield. ¹H NMR (CD₂Cl₂) δ 7.4 (bd), 7.0 (bd), 6.9 (bd), 6.4 (bd), 6.3 (bd), 2.2 (bd, two overlapping signals), 1.6 (bd).

Fabrication and Characterization of Light-Emitting Devices: Devices were fabricated on indium tin oxide (ITO) coated glass substrates (Donnelly Corporation) with a nominal sheet resistance of 20 ohms/sq which had been ultrasonicated in acetone, methanol and isopropanol, dried in a stream of nitrogen, and then plasma etched for 60 seconds. Polymer layers (40 nm) were formed by spin casting from chlorobenzene solutions (10 g/L). The second layer consisted of vacuum vapor deposited tris(8-quinolinato)aluminum (Alq) (60 nm), which had been purified by recrystallization and sublimation prior to deposition. Mg cathodes (200 nm) were thermally deposited at a rate of 8 Å/s through a shadow mask to create devices 3×5 mm² in area. Current-voltage and light output characteristics of the devices were measured in forward bias. Device emission was measured using a silicon photodetector at a fixed distance from the sample (12 cm). The response of the detector had been calibrated using several test devices, for which the total power emitted in the forward direction was measured with a NIST traceable integrating sphere (Labsphere). Photometric units of cd/m² were calculated using the forward output power and the electroluminescence spectra of the devices. Efficiencies were measured in units of external quantum efficiency (% photons/electron). Cathode deposition and device characterization were performed in a nitrogen dry box (Vacuum Atmospheres).

Preparation of 1-bromo-4-(m-tolylphenylamino)benzene (1)

Tris(dibenzylideneacetone)dipalladium(0) (Pd₂dba₃) (4.00 g, 4.37 mmol), 1,1′-bis(diphenylphosphino)ferrocene (dppf) (3.63 g, 6.55 mmol) and 1,4-dibromobenzene (206 g, 873 mmol) were dissolved in 400 mL dry toluene and stirred for 15 min. Sodium tert-butoxide (41.9 g, 436 mmol) and m-tolylphenylamine (50 mL, 290 mmol) were then added. The reaction mixture was warmed to 100° C. for 16 h. Thereafter, the reaction mixture was poured into water (1 L) and ether (500 mL), and the aqueous layer was extracted with ether. The combined organics were dried over MgSO₄, and the solvent evaporated under reduced pressure. Column chromatography (silica, hexanes) afforded 63.4 g (64%) of product 1. ¹H NMR (CDCl₃) δ 7.33-7.23 (m, 4H), 7.15 (t, 1H, J=7.7 Hz), 7.08-6.86 (m, 8H), 2.27 (s, 3H); ¹³C NMR (CDCl₃) δ 147.5, 147.3, 147.1, 139.3, 132.1, 129.3, 129.2, 125.2, 125.0, 124.3, 124.2, 123.0, 121.8, 114.6, 21.4, HRMS calcd. for C₁₉H₁₆BrN [M⁺] 339.0446, found 339.0452; Anal. calcd. for C₁₉H₁₆BrN: C 67.47, H 4.77, N 4.14. Found: C 67.42, H 4.71, N 4.18.

### Methods for the Synthesis of Monomers comprising Cyclic Olefins

Preparation of 1-(hex-5-enyl)-4-(m-tolylphenylamino)benzene (15)

12 g (35 mmol) of 1 were dissolved in 500 mL tetrahydrofuran (“THF”) and treated with 2 equivalents of tert-BuLi (1.66 M solution in hexanes, 45 mL) at −78° C. under inert gas atmosphere. 14.5 g (89 mmol) of 6-bromohexene were added, and the solution was allowed to slowly warm up to room temperature. After 5 hours, water was added to the reaction mixture. The mixture was extracted with ether. After drying the organic phase over MgSO₄, the solvent and excess of 6-bromohexene were removed under reduced pressure yielding 11.4 g (94%) of colorless oil. ¹H NMR (CD₂Cl₂) δ 7.3-6.8 (m, 13H), 5.85 (m, 1H), 5.00 (m, 2H), 2.58 (t, 2H, J=7.7 Hz), 2.25 (s, 3H), 2.12 (m, 2H), 1.65 (m, 2H), 1.47 (m, 2H); ¹³C NMR (CD₂Cl₂) δ 147.9, 147.7, 145.2, 138.8, 138.7, 137.2, 128.8, 128.7, 128.6, 124.3, 124.2, 123.2, 123.0, 121.8, 120.8, 113.8, 34.8, 33.3, 30.7, 28.3, 20.8; HRMS calcd. for C₂₅H₂₇N [M⁺] 341.2139, found 341.2143; Anal. calcd. for C₂₅H₂₇N: C 87.93, H 7.97, N 4.10: Found: C 87.85, H 7.89, N 3.97.

Preparation of 1-(6-hydroxyhexyl)-4-(m-tolylphenylamino)benzene (16)

11.4 g (33.3 mmol) of 15 were placed into a 500 mL flask and 150 mL of a 0.5 M solution of 9-borabicyclo[3.3.1]nonane (9-BBN) in THF were added under inert gas atmosphere. The reaction mixture was stirred at room temperature for 24 hours and cooled to 0° C. 26 mL of 3M NaOH and 22 mL of H₂O₂ solution (30%) were added slowly. The reaction mixture was warmed up to 50° C. and kept at 50° C. for 2 hours. The aqueous phase was extracted with ether, and the product was purified by column chromatography (silica, 30% ethylacetate in hexanes). Yield: 8.8 g, 74%. ¹H NMR (CD₂Cl₂) δ 7.3-6.8 (m, 13H), 3.60 (t, 2H, J=6.5 Hz), 2.58 (t, 2H, J=7.7 Hz), 2.25 (s, 3H), 1.7-1.5 (m, 4H), 1.5-1.3 (m, 4H); ¹³C NMR (CD₂Cl₂) δ 147.9, 147.7, 145.2, 139.1, 137.8, 128.8, 128.7, 128.6, 124.3, 124.2, 123.5, 123.4. 121.8, 120.8, 62.8, 35.3, 32.8, 31.6, 29.2, 25.7, 20.8, HRMS calcd. for C₂₅H₂₉NO [MH⁺] 360.2318, found 360.2327.

Preparation of 1-(2-hydroxyethyl)-4-(m-tolylphenylamino)benzene (17)

4-bromophenethanol was protected with a triphenylmethyl (trityl) group by stirring a solution of 4-bromophenethanol (20.3 g, 0.101 mol), trityl chloride (30.97 g, 0.111 mol), and 4-dimethylaminopyridine (200 mg) in pyridine (200 mL) under nitrogen atmosphere at 70° C. for 33 hours. The protected compound was purified by phase separation between methylene chloride and water and flash column chromatography (silica, 10% ethylacetate in hexanes). The yield of the trityl protected 4-bromophenethanol was 74%. The protected 4-bromophenethanol (31.10 g, 70.16 mmol) was coupled to m-anisidine (13.3 mL, 77.2 mmol) following the procedure for Pd-catalyzed amination as described for 1 (Bellmann, E. et al. Chem Mater 10:1668 (1998). The reaction time needed was 24 hours at 90° C. The reaction mixture was cooled down to room temperature and separated between ether and water layers. The combined organic layer was concentrated in vacuo. Column chromatography (silica, 20% methylene chloride in hexanes) afforded a mixture of starting materials and the product. This mixture was dissolved in diethyl ether (150 mL) and treated with 98% formic acid (200 mL). The resultant solution was stirred at room temperature for 90 min. After 90 min, the reaction mixture was separated between ether and water layers, and the ether layer was washed with water and saturated aqueous sodium bicarbonate solution. Concentration of the organic layer and column chromatography (silica, 30% ethyl acetate in hexanes) yielded 9.6 g (45% over 2 steps) of a very viscous material. ¹H NMR (CD₂Cl₂) δ 7.25-6.95 (m, 10H), 6.89 (s, 1H), 6.82 (d, 2H, J=7.7 Hz), 3.81 (q, 2H, J=6.3 Hz), 2.79 (t, 2H, J=6.5 Hz), 2.24 (s, 3H), 1.45 (t, 1H, J=5.8 Hz); ¹³C NMR (CD₂Cl₂) δ 148.4, 148.2, 146.6, 139.5, 133.6, 130.2, 129.5, 129.4, 125.1, 124.7, 124.1, 123.9, 122.7, 121.6, 63.8, 38.9, 21.5; HRMS calcd. for C₂₁H₂₂NO [MH⁺] 304.1701, found 304.1696.

Preparation of 1-methoxy-3-(m-tolylphenylamino)benzene (18)

3-Bromoanisole was reacted with 1 equivalent of m-tolylphenylamine in analogy to the procedure described for 1 (Bellmann, E. et al. Chem Mater 10:1668 (1998). The reaction time needed was 8 hours at 95° C. The yield after purification (silica gel column, 5% ethylacetate in hexanes) was 83%. 1H NMR (CD₂Cl₂) δ 7.3-6.85 (m, 10H), 6.65-6.55 (m, 3H), 3.70 (s, 1H), 2.27 (s, 1H); ¹³C NMR (CD₂Cl₂) δ 161.1, 149.8, 148.4, 148.2, 139.7, 130.3, 129.7, 129.6, 125.8, 124.8, 124.4, 123.2, 122.3, 116.8, 110.2, 108.3, 55.7, 21.7; HRMS calcd. for C₂₀H₁₉NO [M⁺] 289.1467, found 289.1469; Anal. calcd. for C₂₀H₁₉NO: C 83.01, H 6.62, N 4.84. Found: C 82.89, H 6.76, N 4.66.

Preparation of 1-hydroxy-3-(m-tolylphenylamino)benzene (19)

13.3 g (53.1 mmol) of BBr₃ were added to a solution of 18 (12.8 g, 44.2 mmol) in 200 mL dry CH₂Cl₂ at −78° C. under inert gas atmosphere. The solution was stirred at −78° C. for 5 min and at room temperature for 3 hours. 150 mL of ice water were added, and the reaction mixture was stirred for another 3 hours. Extraction with CH₂Cl₂ followed by column chromatography (silica, 10% ethylacetate in hexanes) afforded 8.3 g (68%) of 19. ¹H NMR (CD₂Cl₂) δ 7.3-6.85 (m, 10H), 6.62 (m, 1H), 6.50 (t, 1H, J 2.1 Hz), 6.45 (m, 1H), 5.04 (bd s, 1H), 2.27 (s, 3H); ¹³C NMR (CD₂Cl₂) δ 156.9, 150.0, 148.3, 148.1, 130.6, 129.8, 129.7, 126.1, 125.1, 124.7, 123.5, 122.6, 116.4, 110.8, 109.8, 21.7; HRMS calcd. for C₁₉H₁₇NO [M⁺] 275.1310, found 275.1312; Anal. calcd. for C₁₉H₁₇NO: C 82.88, H 6.22, N 5.09. Found: C 82.92, H 6.21, N 5.13.

Preparation of the Ester Monomers 20, 21 and 22

To a solution of the respective alcohol 16, 17 or 19 in THF were added 1 equivalent of norborn-2-ene-5-carbonylchloride³⁵ and 2 equivalents of triethylamine. The reaction mixture was heated to 50° C. for 5 hours in the case of 20 and 21 or stirred at room temperature for 2 hours in the case of 22. The triethylamine-hydrochloride was filtered off, the solvent removed under reduced pressure and the products purified by column chromatography (silica, 5% ethylacetate in hexanes). Yields: 95-100%.

Monomer 20 (mixture of endo and exo): ¹H NMR (CD₂Cl₂) δ 7.3-6.8 (m, 13H), 2H: 6.20 (dd, J₁=3.0 Hz, J₂=5.7 Hz) +6.15 (m) +5.94 (dd, J=3.0 Hz, J₂=5.7 Hz), 4.04 (m, 2H), 2H: 3.21 (bd s) +3.04 (bd s) +2.95 (m), 2.58 (t, 2H, J=7.7 Hz), 2.25 (s and m, 4H), 1.7-1.2 (m, 12H), ¹³C NMR (CD₂Cl₂) δ 174.5, 147.9, 147.7, 145.2, 139.2, 138.0, 137.7, 135.8, 132.4, 128.8, 128.7, 128.6, 124.3, 124.2, 123.2, 123.0, 121.8, 120.8, 64.5, 64.2, 49.6, 46.7, 46.3, 45.8, 43.3, 43.2, 42.7, 41.7, 35.3, 31.5, 30.3, 29.0, 28.7, 25.9, 20.8; HRMS calcd. for C₃₃H₃₇NO₂ [MH⁺] 480.2899, found 480.2902.

Monomer 21 (mixture of endo and exo): ¹H NMR (CD₂Cl₂) δ 7.3-6.8 (m, 13H), 2H: 6.15 (dd, J₁=3.0 Hz, J₂=5.7 Hz and m) +5.76 (dd, J=3.0 Hz, J₂=5.7 Hz), 4.23 (m, 2H), 4H: 3.15 (bd s) +3.0-2.8 (m), 2.25 (s, 3H), 1.9 (m, 1H), 1.5-1.3 (m,4H); ¹³C NMR (CD₂Cl₂) δ 174.0, 147.9, 147.7, 146.0, 138.8, 137.7, 137.3, 132.4, 130.7, 128.8, 128.7, 128.6, 124.3, 124.2, 123.2, 123.0, 121.8, 120.8, 64.5, 64.2, 49.3, 46.7, 46.3, 45.5, 43.0, 42.9, 42.3, 41.4, 34.2, 30.0, 30.3, 28.7, 20.8; HRMS calcd. for C₂₉H₂₉NO₂ [MH⁺] 424.2261, found 424.2276; Anal. calcd. for C₂₉H₂₉NO₂: C 82.24, H 6.90, N 3.31. Found: C 81.86, H 6.96, N 3.32.

Monomer 22 (mixture of endo and exo): ¹H NMR (CD₂Cl₂) 6 7.3-6.6 (m, 13H), 2H: 6.22 (dd, J₁=3.0 Hz, J₂=5.7 Hz) +6.15 (m) +5.98 (dd, J₁=3.0 Hz, J₂=5.7 Hz), 2H: 3.32 (bd s) +3.12 (m) +2.94 (bd s), 2.25 (s, 3H), 1.95 (m, 1H), 1.6-1.2 (m, 4H), ¹³C NMR (CD₂Cl₂) δ 173.7, 152.2, 149.6, 148.1, 147.9, 139.8, 138.9, 138.8, 136.3, 132.8, 130.2, 129.92, 129.90, 126.1, 125.2, 124.9, 123.7, 122.7, 121.0, 120.9, 116.8, 115.8, 64.5, 64.4, 50.3, 47.4, 47.0, 46.5, 44.2, 43.9, 43.3, 42.4, 29.9, 20.8; HRMS calcd. for C₂₇H₂₅NO₂ [MH⁺] 396.1968, found 396.1964; Anal. calcd. for C₂₇H₂₅NO: C 82.00, H 6.37, N 3.54. Found: C 82.06, H 6.51, N 3.58.

Preparation of 1-(6-iodohexyl)-4-(m-tolylphenylamino)benzene (23)

A solution of triphenylphosphine (8.76 g, 33.4 mmol) and imidazole (2.32 g, 33.4 mmol) in acetonitrile/ether (1:3, 80 mL) was cooled to 0° C. and iodine (8.48 g, 33.4 mmol) was added slowly under vigorous stirring, yielding a yellow slurry. The ice bath was removed and the reaction mixture stirred at room temperature for 15 min. A solution of 16 (4 g, 11 mmol) in 20 mL of the acetonitrile/ether solvent mixture was then added dropwise, and the reaction mixture stirred for 1 hour. Filtration through a plug of silica with 5% ethylacetate in hexanes as eluent afforded 5.07 g (97%) of pure product. ¹H NMR (CD₂Cl₂) δ 7.3-6.8 (m, 13H), 3.22 (t, 2H, J=6.9 Hz), 2.58 (t, 2H, J=7.7 Hz), 2.25 (s, 3H), 1.85 (m, 2H), 1.65 (m, 2H), 1.42 (m, 4H); ¹³C NMR (CD₂Cl₂) δ 147.9, 147.7, 145.2, 139.1, 137.6, 128.8, 128.7. 128.6, 124.3, 124.2, 123.5, 123.4, 121.8, 120.8, 35.2, 33.6, 31.4, 30.4, 28.3, 20.8, 7.6; HRMS calcd. for C₂₅H₂₈NI [M⁺] 469.1279, found 469.1267; Anal. calcd. for C₂₅H₂₈NI: C 63.97, H 6.01, N 2.98. Found: C 63.93, H 5.96, N 2.80.

Preparation of 1-(2-iodoethyl)-4-(m-tolylphenylamino)benzene (24)

Compound 24 was prepared analogously to compound 23 in 97% yield. ¹H NMR (CD₂Cl₂) δ 7.3-6.8 (m, 13H), 3.35 (t, 2H, J=7.2 Hz), 3.12 (t, 2H, J=7.2 Hz), 2.25 (s, 3H); ¹³C NMR (CD₂Cl₂) δ 147.9, 147.7, 146.7, 139.3, 135.0, 129.18, 129.16, 129.0, 125.0, 124.0, 123.8, 122.6, 121.5, 39.8, 20.8, 6.3; HRMS calcd. for C₂₁H₂₀NI [MH⁺] 414.0726, found 414.0719; Anal. calcd. for C₂₁H₂₀NI: C 61.03, H 4.88. N 3.39. Found: C 61.06, H 4.96, N 3.28.

Preparation of 1-(6-(norborn-2-ene-5-methoxy)hexyl)-4-(m-tolyl-phenylamino)benzene (25)

Norborn-2-ene-5-methanol (0.53 g, 4.3 mmol) was dissolved in 20 mL THF and treated with NaH (0.15 g, 6.4 mmol) at 0° C. After stirring for 15 min, a solution of 23 (4 g, 4.3 mmol) in THF (10 mL) was added dropwise. The reaction mixture was allowed to slowly warm up to room temperature and stirred for 6 hours. Water was added and the reaction mixture extracted with ether. Removing the solvent under reduced pressure and column chromatography afforded 0.44 g (22%) of the desired product as a mixture of endo- and exo-isomers. ¹H NMR (CD₂Cl₂) δ 7.3-6.8 (m, 13H), 2H: 6.12 (dd, J₁=3.0 Hz, J₂=5.7 Hz) +6.09 (m) +5.95 (dd, J₁=3.0 Hz, J₂=5.7 Hz), 4H: 3.37 (m) +3.23 (t, J=7.2 Hz) +3.13 (dd, J₁=6.6 Hz, J₂=9.3 Hz) +3.00 (t, J=9.0 Hz), 3H: 2.90 (bd s) +2.79 (bd s) +2.74 (bd s) +2.34 (m), 2.58 (t, 2H, J=7.7 Hz), 2.25 (s, 3H), 12H: 1.83 (m) +1.7-1.5 (m) +0.51(m); ¹³C NMR (CD₂Cl₂) δ 147.9, 147.7, 145.2, 138.8, 137.5, 136.7, 136.3, 132.4, 128.8, 128.7, 128.6, 124.3, 124.2, 123.2, 123.0, 121.8, 120.8, 75.1, 74.2, 70.6, 70.4, 49.1, 44.7, 43.8, 43.5, 42.0, 41.3, 48.71, 48.57, 35.0, 33.3, 31.3, 20.1, 29.5, 29.3, 29.0, 28.8, 25.8, 25.0, 20.8, 7.1, HRMS calcd. for C₃₃H₃₉NO [M⁺] 465.3032, found 465.3028.

Preparation of 1-(norborn-2-ene-5-methoxy)-3-(m-tolylphenylamino)benzene (26)

A solution of norborn-2-ene-5-methanol (1.8 g, 14.5 mmol), 19 (4 g, 14.5 mmol) and triphenylphosphine (5.7 g, 22 mmol) in 250 mL THF was cooled to 0° C. 2.53 g (14.5 mmol) diethyl azodicarboxylate (DEAD) were added dropwise, and the solution stirred at room temperature for 6 hours. After addition of water the reaction mixture was extracted with ether. Purification by column chromatography (silica, 5% ethylacetate in hexanes) yielded 2.64 g (48%) of product as a mixture of endo- and exo-isomers. ¹H NMR (CD₂Cl₂) δ 13H: 7.3-6.85 (m) +6.75-6.55 (m), 2H: 6.18 (dd, J₁=3.0 Hz, J₂=5.7 Hz) +6.15 (m) +5.98 (dd, J₁=3.0 Hz, J₂=5.7 Hz), 2H: 4.00 (dd, J₁=6.0 Hz, J₂=9.3 Hz) + 3.79 (t, J=9.0 Hz) +3.66 (dd, J₁=6.3 Hz, J₂=9.0 Hz) +3.15 (t, J=9.0 Hz), 7H: 3.05 (bd s) +2.89 (m) +2.55 (m) +1.92 (m) +1.51 (m) +1.45-1.2 (m) + 0.63 (m), 2.30 (s, 3H); ¹³C NMR (CD₂Cl₂) δ 160.6, 149.8, 149.7, 148.5, 148.3, 139.6, 138.1, 137.4, 137.1, 133.0, 130.4, 130.3, 129.8, 129.6, 125.8, 124.9, 124.4, 123.2, 122.4, 117.1, 111.2, 111.1, 109.1, 72.8, 72.0, 50.1, 45.7, 44.5, 44.3, 42.9, 42.2, 39.2, 39.0, 30.2, 29.7, 22.1; HRMS calcd. for C₂₇H₂₇NO [MH⁺j] 382.217, found 382.2175, Arial. calcd. for C₂₇H₂₇NO: C 85.00, H 7.13, N 3.67. Found: C 84.78, H 7.18, N 3.68.

General Polymerization Procedure:

In a nitrogen filled dry box, a solution of the monomer and a solution of the initiator 27 in CH₂Cl₂ were prepared. (1 mL solvent was used for every 100 mg monomer. The initiator was dissolved in minimum amount of solvent. Monomer to initiator ratio was 100.) The reaction was initiated by adding the initiator solution to the vigorously stirred monomer solution. The reaction mixture was stirred for 2.5 hours. Outside the dry box, the reaction was terminated by adding a small amount of ethylvinylether and poured into methanol to precipitate the polymer. The polymer was purified by dissolving in CH₂Cl₂ and reprecipitating into methanol several times and drying in vacuo. Isolated yields ranged from 85 to 95% (100% by NMR).

Poly-20: ¹H NMR (CDCl₃) δ 7.3-6.8 (bd in, 13H), 5.6-5.2 (bd, 2H), 4.0 (bd s, 2H), 5H: 3.2 (bd) +2.9 (bd) +2.6 (2 broad signals overlap), 2.2 (bd, 3H), 12H: 2.0 (bd) +1.7 (bd) +1.4 (bd) +1.2 (bd).

Poly-21: ¹H NMR (CDCl₃) δ 7.3-6.8 (bd m, 13H), 5.6-5.2 (bd, 2H), 4.0 (bd s, 2H), 5H: 3.2 (bd) +2.9 (2 broad signals overlap) +2.5 (bd), 2.2 (bd, 3H), 4H: 2.0 (bd) +1.8 (bd) +1.4 (bd).

Poly-22: ¹H NMR (CDCl₃) δ 7.3-6.6 (bd m, 13H), 5.6-5.2 (bd, 2H), 3.2-2.3 (bd, 3H), 2.2 (bd, 3H), 4H: 2.1-1.6 (bd) +1.4 (bd).

Poly-25: ¹H NMR (CDCl₃) δ 7.3-6.8 (bd m, 13H), 5.6-5.2 (bd, 2H), 4H: 3.4 (bd) +3.2 (bd), 3.0-2.4 (bd, 5H), 2.2 (bd, 3H), 12H: 1.9 (bd) +1.6 (bd) +1.4 (bd) +1.2 (bd).

Poly-26: ¹H NMR (CDCl₃) δ 7.3-6.8 (bd m, 13H), 5.6-5.2 (bd, 2H), 2H: 3.8 (bd) +3.6 (bd), 3.0-2.2 (bd, 3H), 2.2 (bd, 3H), 4H: 2.0-1.5 (bd) +1.2 (bd).

Fabrication and Characterization of Light Emitting Devices:

Devices were fabricated on indium tin oxide (ITO) coated glass substrates with a nominal sheet resistance of 20 ohms/sq (Donnelly Corporation) which had been ultrasonicated in acetone, methanol and isopropanol, dried in a stream of nitrogen, and then plasma etched for 60 seconds. Polymer layers (40 nm) were formed by spin casting from chlorodibenzene solutions (10 g/L). Two-layer devices were fabricated by spin-casting of the polymers P1-P5 from chlorobenzene on ITO resulting in HTLs of 20-40 nm thickness. Mg cathodes (200 nm) were thermally deposited at a rate of 8 Å/s through a shadow mask to create devices 3×5 mm in area.

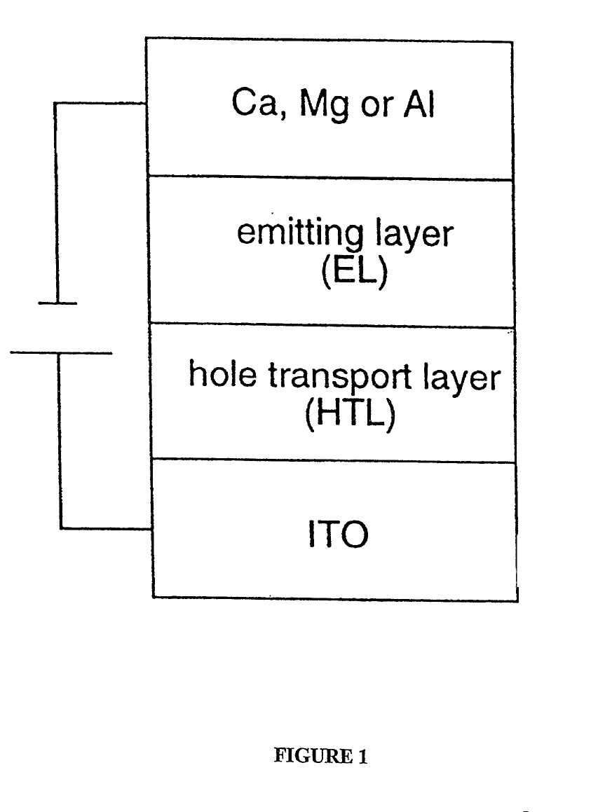

A schematic of the resulting two layer LED is shown in FIG. 1. In optimized devices, the second layer consists of Alq₃ doped with quinacridone; a cathode was prepared as a composite cathode of LiF/Al. The second layer consisted of vacuum vapor deposited Alq₃ (60 nm) which had been purified by recrystallization and sublimation prior to deposition.

Current-voltage and light output characteristics of the devices were measured in forward bias. Device emission was measured using a silicon photodetector at a fixed distance from the sample (12 cm). The response of the detector had been calibrated using several test devices, for which the total power emitted in the forward direction was measured with a NIST traceable integrating sphere (Labsphere). Photometric units of cd/m² were calculated using the forward output power and the electroluminescence spectra of the devices. Efficiencies were measured in units of external quantum efficiency (% photons/electron). Cathode deposition and device characterization were performed in a nitrogen dry box (VAC).

Crosslinking Procedure for poly-20, poly-21, poly-22, poly 25 and poly-26:

Polymer films were placed 7 inches away from a 150 W Hg:X lamp with a glass diffuser in between for uniform exposure and irradiated for 1 hour.

The following publications are incorporated herein by reference:

(1) Tsutsui, T. MRS Bulletin June 1997, 39.

(2) Van der Auweraer, M.; De Schryver, F. C.; Borsenberger, P. M.; Fitzgerald, J. J. J. Phys. Chem. 1993, 97, 8808.

(3) Borsenberger, P. M.; Pautmeier, L.; Richert, R.; Bässler, H. J. Chem. Phys. 1991, 94, 8276.

(4) Gruenbaum, W. T.; Sorriero, L. J.; Borsenberger, P. M.; Zumbulyadis, N. Jpn. J. Appl. Phys. 1996, 35, 2714.

(5) Heun, S.; Borsenberger, P. M. Physica B 1995, 216, 43.

(6) Bässler, H. Phys. Status Solidi (b) 1993, 175, 15 and references therein.

(7) Tang, C. W.; VanSlyke, S. A. Appl. Phys. Lett. 1987, 51, 913.

(8) Tang, C. W.; VanSlyke, S. A.; Cheng, C. H. J. Appl. Phys. 1989, 65, 3610.

(9) Kalinowski, J.; Di Marco, P.; Cocchi, M.; Fattori, V., Camaioni, N., Duff, J. Appl. Phys. Lett. 1996, 68, 2317.

(10) Tanaka, K.; Tokito, S.; Taga, Y; Okada, A. J. Chem Soc., Chem. Commun. 1996, 2175.

(11) Tokito, S.; Tanaka, H.; Okada, A.; Taga, Y. Appl. Phys. Lett. 1996, 69, 878.

(12) Adachi, C.; Tokito, S.; Tsutsui, T.; Saito, S. Jpn. J. Appl. Phys. 1988, 27, L269.

(13) Mori, T.; Obata, K.; Imaizumi, K.; Mizutani, T. Appl. Phys. Lett. 1996, 69, 3309.

(14) Burrows, P. E.; Shen, Z.; Bulovic, V.; McCarty, D. M.; Forrest, S. R.; Cronin, J. A., Thompson, M. E. J. Appl. Phys. 1996, 79, 7991.

(15) Lin, C. P.; Tsutsui, T.; Saito, S. New Polymeric Mater. 1995, 4, 277.

(16) Kim, D. U.; Aminaka, E.; Tsutsui, T., Saito, S. Jpn. J. Appl. Phys. 1995, 34, 6255.

(17) Kim, D. U., Tsutsul, T. J. Appl. Phys. 1996, 80, 4785.

(18) Kolb, E. S.; Gaudiana, R. A.; Mehta, P. G. Macromolecules 1996, 29, 2359.

(19) Hosokawa, C.; Kawasaki, N.; Sakamoto, S.; Kusumoto, T. Appl. Phys. Lett. 1992, 61, 2503.

(20) Kraft, A.; Burn, P. L.; Holmes, A. B.; Bradley, D. D. C.; Friend. R. H.; Martens, J. H. F. Synthetic Metals 1993, 55-57, 4163.

(21) Gustaffson, G.; Cao, Y.; Treacy, G. M.; Klavetter, F.; Colaneri, N.; Heeger, A. J. Nature 1992, 357, 477.

(22) Grubbs, R. H.; Tumas, W. Science 1989, 243, 907.

(23) Schrock, R. R. Acc. Chem. Res. 1990, 23, 158.

(24) Maughon, B. R.; Weck, M.; Mohr, B.; Grubbs, R. H. Macromolecules 1997, 30, 257.

(25) Maughon, B. R.; Grubbs, R. H. Macromolecules 1997, 30, 3459.

(26) Boyd, T. J.; Geerts, Y.; Lee, J.; Fogg, D. E.; Lavoie, G. G.; Schrock, R. R.; Rubner, M. F. Macromolecules 1997, 30, 3553.

(27) Percec, V.; Schlueter, D. Macromolecules 1997, 30, 5783.

(28) Biagini, S. C. G.; Gibson, V. C.; Giles, M. R.; Marshall, E. L.; North, M. J. Chem. Soc., Chem. Commun. 1997, 1097.

(29) Gibson, V. C.; Marshall, E. L.; North, M.; Robson, D. A.; Williams, P. J. J. Chem. Soc. Chem. Commun. 1997, 1095.

(30) Gratt, J.; Cohen, R. E. Macromolecules 1997, 30, 3137.

(31) Wagaman, M. W.; Bellmann, E.; Grubbs, R. H. Phil. Trans. R. Soc. Lond. A 1997, 355, 727.

(32) Schneider, M. F.; Lucas, N.; Velder, J.; Blechert, S. Angew. Chem., Int. Ed. Eng. 1997, 36, 257.

(33) Schwab, P.; Grubbs, R. H., Ziller, J. W. J. Am. Chem. Soc. 1996, 118, 100.

(34) Schwab, P.; France, M. B.; Ziller, J. W.; Grubbs, R. H. Angew. Chem., Int. Ed. Eng. 1995, 34, 2039.

(35) Jacobine, A. F.; Glaser, D. M.; Nakos, S. T. Polym. Mater. Sci. Eng. 1989, 60, 211.

(36) Wolfe, J. P.; Rennels, R. A.; Buchwald, S. L. Tetrahedron 1996, 52, 7525.

(37) Wolfe, J. P.; Wagaw, S.; Buchwald, S. L. J. Am. Chem. Soc. 1996, 118, 7215.

(38) Driver, M. S.; Hartwig, J. F. J. Am. Chem. Soc. 1996, 118, 7217.

(39) Thayumanavan, S.; Barlow, S.; Marder, S. R. Chem. Mater. 1997, 9, 3231.

(40) Tamao. K.; Sumitani, K.; Kumada, M. J. Am. Chem. Soc. 1972, 94, 4374.

(41) Nugent, W. A.; McKinney, R. J. J. Org. Chem. 1985, 50, 5370.

(42) Millar, J. G.; Underhill, E. W. J. Org. Chem. 1986, 51, 4727.

(43) Nakano, I,; Mimura, M.; Hayashida, M.; Kimura, K.; Nakanishi, T. Heterocycles 1983, 20, 1975.

(44) Domes, H.; Fischer, R.; Haarer, D.; Strohrlegl, P. Makromol. Chem. 1989. 190, 165.

(45) Partridge, R. H. Polymer, 1983, 24, 748.

(46) U.S. Pat. Nos: 5,428,090; 4,935,487; 5,728,801; and 5,486,439.

(47) Yang, Y. MRS Bulletin June 1997, 39 and references therein.

(48) Nalwa, H. S.; Miyata, S., Eds. Nonlinear Optics of Organic Molecules and Polymers CRC Press: New York, 1997.

What is claimed is:

1. A polymer of triarylamine monomers, said monomers having the structure 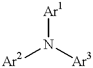
wherein each of Ar¹, Ar², Ar³ is independently a substituted or unsubstituted aryl radical, or a fused ring aromatic compound consisting of said radicals, and wherein one of Ar¹, Ar² and Ar³ is a vinylated phenyl group.

2. A polymer according to claim 1 wherein said aryl radicals are selected from the group consisting of
(a) phenyl;
(b) biphenyl;
(c) anthracenyl;
(d) phenanthracenyl;
(e) naphthyl;
(f) fluorenyl; and
(g) pyrenyl.

3. A polymer of substituted triarylamine monomers according to claim 1 wherein said aryl ring has a substituent selected from the group consisting of
(a) OR¹;
(b) Cl, Br, I or F;
(c) NR¹R²;
(d) C(O)OR¹;
(e) C(O)NR¹R²;
(f) NR¹C(O)R²;
(g) NO₃;
(h) N═C═O;
(i) C═N═O:
(j) NR¹C(O)NR²R³;
(k) SR¹;
(l) C(O)R¹;
(m) OC(O)R¹;
(n) C₁ to C₂₀ alkyl;
(o) C₂ to C₂₀ alkenyl;
(p) C₂ to C₂₀ alkynyl; and
(q) aryl;
wherein R¹, R² and R³ are independently selected from the group consisting of C₁ to C₂₀ alkyl; C₂ to C₂₀ alkenyl; C₂ to C₂₀ alkynyl; and aryl

4. A polymer according to claim 1 consisting of triarylamine or triaryldiamine monomers of one of the structures:

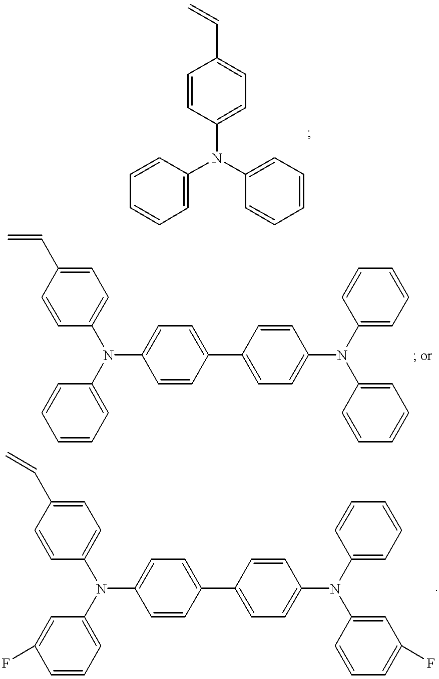

5. A homopolymer according to any one of claims 1-4.

6. A copolymer or block polymer according to any one of claims 1-4.

7. A polymerizable monomer comprising a triarylamine radical, a linker group, and a cyclic olefin, said cyclic olefin being capable of undergoing a ring-opening polymerization reaction, and said linker component being covalently attached to the triarylamine component and to the cyclic olefin, wherein said triarylamine has the structure 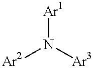
wherein each of AR¹, AR², AR³ are independently a substituted or unsubstituted aryl radical, or a fused ring aromatic compound consisting of said radicals.

8. A polymer according to claim 7 wherein the aryl radicals of said triarylamine are selected from the group consisting of
(a) phenyl;
(b) biphenyl;
(c) anthracenyl;
(d) phenanthracenyl;
(e) naphthyl;
(f) fluorenyl; and
(g) pyrenyl.

9. A polymer according to claim 7 whrien the aryl radicals of said triarylamine are substituted and said substituents are selected from the group consisting of
(a) OR¹;
(b) Cl, Br, I or F;
(c) NR¹R²;
(d) C(O)OR1;
(e) C(O)NR¹R^{2;}
(f) NR¹C(O)R²;
(g) NO₃;
(h) N═C═O;
(i) C═N═O:
(j) NR¹C(O)NR²R³;
(k) SR¹;
(l) C(O)R¹;
(m) OC(O)R¹;
(n) C₁ to C₂₀ alkyl;
(o) C₂ to C₂₀ alkenyl;
(p) C₂ to C₂₀ alkynyl; and
(q) aryl;
wherein R¹, R² and R³ are independently selected from the group consisting of C₁ to C₂₀ alkyl; C₂ to C₂₀ alkenyl; C₂ to C₂₀ alkynyl; and aryl

10. A polymer according to claim 7 having wherein the covalently bound linker and cyclic olefin together have the structure 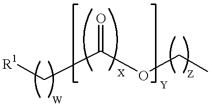
wherein R¹ is a cyclic olefin, x and y are either zero or 1, and, w and z are zero or any positive integer.

11. A polymer according to claim 7 comprising monomeric units wherein said linker component is selected from the group consisting of C₁-C₂₀ alkyl, C₂-C₂₀ alkenyl, C₅-C₈ cycloalkyl, and aryl groups.

12. A polymer according to claim 7 comprising monomeric units wherein the cyclic olefin component is selected from the group consisting of norbornene, norboranadiene, cyclopentene, dicyclopentadiene, cyclobutene, cycloheptene, cyclooctene, 7-oxanorbornene, 7-oxanorbornadiene, and cyclododecene.

13. A polymer according to claim 7 comprising monomeric units wherein said cyclic olefin has the one of the following structures: 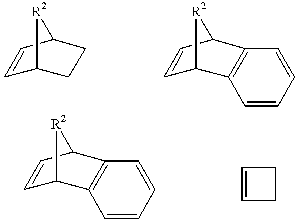
wherein R² is selected from the group consisting of CH₂, C-alkyl, C-dialkyl, O, N-alkyl and NH.

14. A polymer according to claim 7 wherein Ar¹, Ar², and Ar³ are each independently either unsubstituted phenyl or substituted phenyl; R¹ is an unsubstituted or a substituted norbornene; w, x, and y are either zero or 1; and z is 0 to 18.

15. A polymer according to claim 14 wherein, w, x, and y are either zero or 1, and z is less than 5.

16. A polymer according to any one of claims 7-15 wherein any of said triarylamine, linker, and cyclic olefin components is further substituted with one or more substituents selected from the group consisting of halide, C₁ 1-C₂₀ alkyl, C₂-C₂₀ alkenyl, C₂-C₂₀ alkynyl, C₁-C₂₀ alkoxy, and aryl, or further include one or more functional groups

17. A polymer according to claim 16 wherein said functional groups are selected from the group consisting of hydroxyl, thiol, thioether, ketone, aldehyde, ester, ether, amine, imine, amide, nitro, carboxylic acid, carbonate, isocyanate, carbodiimide, carboalkoxy, carbamate, and halogen.

18. A homopolymer according to claim 7.

19. A copolymer or block copolymer according to claim 7.

20. A hole-transporting layer in a light emitting device comprising a polymer according to claim 1 or claim 7.

21. A photorefractive material comprising a polymer according to claim 1 or claim 7.

22. A solid state electrolyte in a solar cell which is based on a wide-bandgap semiconductor comprising a polymer according to claim 1 or claim 7.
